(19) United States
(12) Patent Application Publication
(10) Pub. No.: US 2024/0282802 A1
(43) Pub. Date: Aug. 22, 2024

(54) DISPLAY DEVICE

(71) Applicant: Samsung Display Co., LTD., Yongin-si (KR)

(72) Inventors: Sung Chul HONG, Yongin-si (KR); Kyung Bae KIM, Yongin-si (KR); Yeon Kyung KIM, Yongin-si (KR)

(73) Assignee: Samsung Display Co., LTD., Yongin-si (KR)

(21) Appl. No.: 18/541,235

(22) Filed: Dec. 15, 2023

(30) Foreign Application Priority Data
Feb. 20, 2023 (KR) 10-2023-0022371

(51) Int. Cl. H01L 27/15

(52) U.S. Cl. CPC H01L 27/156

(57) ABSTRACT

A display device comprises a first voltage line disposed in a first metal layer on a substrate providing a high-level voltage, a vertical voltage line disposed on a side of the first voltage line providing a low-level voltage, a first transistor disposed in an active layer on the first metal layer and including a drain electrode, an active region, a source electrode, and a gate electrode, a first anode connection electrode disposed in a third metal layer on the second metal layer and electrically connected to the source electrode of the first transistor, a first electrode and a second electrode that are disposed in a fourth metal layer on the third metal layer, and a plurality of light-emitting element areas including a plurality of light-emitting elements aligned between the first and second electrodes and spaced apart from the first voltage line and the vertical voltage line in a plan view.

### CROSS-REFERENCE TO RELATED APPLICATION(S)

This application claims priority to and benefits of Korean Patent Application No. 10-2023-0022371 under 35 U.S.C. § 119, filed on Feb. 20, 2023, in the Korean Intellectual Property Office, the entire contents of which are incorporated herein by reference.

### BACKGROUND

### 1. Technical Field

The disclosure relates to a display device.

### 2. Description of the Related Art

As information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, and an organic light-emitting display device. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel. A light-emitting element may be an organic light-emitting diode using an organic material as a fluorescent material or an inorganic light-emitting diode using an inorganic material as a fluorescent material.

### SUMMARY

An aspect of the disclosure provides a display device with improved reliability by suppressing the influence of a high-level voltage line and a low-level voltage line so that the light-emitting elements can be readily aligned during a process of aligning light-emitting elements.

It should be noted that aspects of the disclosure are not limited to the above-mentioned aspect; and other aspects of the disclosure will be apparent to those skilled in the art from the following descriptions.

According to an embodiment, a display device may include a first voltage line disposed in a first metal layer on a substrate and that provides a high-level voltage, a vertical voltage line disposed on a side of the first voltage line and that provides a low-level voltage, a first transistor disposed in an active layer on the first metal layer and including a drain electrode electrically connected to the first voltage line, an active region adjacent to the drain electrode, a source electrode adjacent to the active region, and a gate electrode disposed in a second metal layer on the active layer, a first anode connection electrode disposed in a third metal layer on the second metal layer and electrically connected to the source electrode of the first transistor, a first electrode and a second electrode that are disposed in a fourth metal layer on the third metal layer and extended in a first direction, and a plurality of light-emitting element areas including a plurality of light-emitting elements aligned between the first and second electrodes and spaced apart from the first voltage line and the vertical voltage line in a plan view.

The display device may further include an initialization voltage line disposed between the first voltage line and the vertical voltage line in the first metal layer. The plurality of light-emitting elements may overlap the initialization voltage line.

The initialization voltage line may not receive the high-level voltage or the low-level voltage in a process of aligning the plurality of light-emitting elements.

The display device may further include a data line disposed in the first metal layer and that provides a data voltage, a second transistor that provides the data voltage to the gate electrode of the first transistor, a third transistor electrically connecting the initialization voltage line with the source electrode of the first transistor, and a first capacitor including a first capacitor electrode electrically connected to the gate electrode of the first transistor and a second capacitor electrode electrically connected to the source electrode of the first transistor.

The display device may further include a gate line disposed in the third metal layer and that provides a gate signal, a first auxiliary gate line disposed between the first capacitor and the first data line and that provides the gate signal to the second transistor, and a second auxiliary gate line disposed between the initialization voltage line and the first voltage line and that provides the gate signal to the third transistor.

The display device may further include a first auxiliary electrode disposed in the second metal layer, overlapping the first voltage line, and electrically connected to the first voltage line, and a second auxiliary electrode disposed in the third metal layer, overlapping the first voltage line, and electrically connected to the first voltage line.

The light-emitting element areas may be spaced apart from the first and second auxiliary electrodes in a plan view.

The second auxiliary electrode may electrically connect the first voltage line with the drain electrode of the first transistor.

The display device may further include a third auxiliary electrode disposed in the second metal layer, overlapping the vertical voltage line, and electrically connected to the vertical voltage line, and a fourth auxiliary electrode disposed in the third metal layer, overlapping the vertical voltage line, and electrically connected to the vertical voltage line.

The light-emitting element areas may be spaced apart from the first and second auxiliary electrodes in a plan view.

The display device may further include a horizontal voltage line disposed in the third metal layer and electrically connected to the first voltage line, and a second voltage line disposed in the third metal layer and electrically connected to the vertical voltage line.

The first electrode may be electrically connected to the horizontal voltage line and receives the high-level voltage, and the second electrode may be electrically connected to the second voltage line and receives the low-level voltage.

The display device may further include a first contact electrode disposed in a fifth metal layer on the fourth metal layer and electrically connected to an end of each of the light-emitting elements, and a second contact electrode disposed in the fifth metal layer and electrically connected between an opposite end of each of the light-emitting elements and a second voltage line.

According to an embodiment, a display device may include a first voltage line disposed in a first metal layer on a substrate and that provides a high-level voltage, an initialization voltage line disposed on a side of the first voltage line and that provides an initialization voltage, a vertical voltage line disposed on the side of the first voltage line and that provides a low-level voltage, a data line disposed in the first metal layer, a first transistor disposed in an active layer on the first metal layer and including a drain electrode electrically connected to the first voltage line, an active region adjacent to the drain electrode, a source electrode adjacent to the active region, and a gate electrode disposed in a second metal layer on the active layer, a connection electrode disposed in a third metal layer on the second metal layer, electrically connected to the initialization voltage line and extended to a side of the data line, a first electrode and a second electrode that are disposed in a fourth metal layer on the third metal layer and extended in a first direction, and a plurality of light-emitting element areas including a plurality of light-emitting elements aligned between the first and second electrodes and spaced apart from the first voltage line and the vertical voltage line in a plan view.

The plurality of light-emitting elements may overlap the initialization voltage line.

The display device may further include a second transistor that provides a data voltage to the gate electrode of the first transistor, a third transistor electrically connecting the initialization voltage line with the source electrode of the first transistor, and a first capacitor including a first capacitor electrode electrically connected to the gate electrode of the first transistor and a second capacitor electrode electrically connected to the source electrode of the first transistor.

The connection electrode may electrically connect a source electrode of the third transistor with the initialization voltage line.

The display device may further include a gate line disposed on the third metal layer and that provides a gate signal, and an auxiliary gate line disposed between the first capacitor and the first data line and that provides the gate signal to the second and third transistors.

The connection electrode may overlap at least a part of the auxiliary gate line.

The display device may further include an auxiliary electrode disposed in the third metal layer, overlapping the initialization voltage line, and electrically connected to the initialization voltage line. The connection electrode and the auxiliary electrode may be integral to each other.

According to embodiments of the disclosure, the influence by a first voltage line providing a high-level voltage and a vertical voltage line providing a low-level voltage may be suppressed so that the light-emitting elements can be readily aligned between first and second electrodes during a process of aligning light-emitting elements, thereby improving the reliability of a display device.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view showing a display device according to an embodiment of the disclosure.

FIG. 2 is a schematic view showing pixels and lines of a display device according to an embodiment.

FIG. 3 is a schematic circuit diagram showing a pixel of a display device according to an embodiment of the disclosure.

FIGS. 4 and 5 are schematic plan views showing a thin-film transistor layer of a display device according to an embodiment.

FIG. 6 is a schematic cross-sectional view, taken along line I-I′ of FIGS. 4 and 5.

FIG. 7 is a schematic plan view showing an emission layer of a display device according to an embodiment of the disclosure.

FIG. 8 is a schematic plan view showing a fourth metal layer of a display device according to an embodiment of the disclosure.

FIG. 9 is a schematic plan view showing a fifth metal layer of a display device according to an embodiment of the disclosure.

FIG. 10 is a schematic cross-sectional view of a display device according to an embodiment of the disclosure.

FIG. 11 is a schematic plan view showing a thin-film transistor layer and light-emitting element areas of a display device according to an embodiment.

FIGS. 12 and 13 are schematic plan views showing a thin-film transistor layer of a display device according to another embodiment.

FIG. 14 is a schematic cross-sectional view, taken along line II-II′ of FIGS. 12 and 13.

FIG. 15 is a schematic plan view showing a thin-film transistor layer and light-emitting element areas of a display device according to another embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words and mean non-limiting examples of devices or methods employing one or more aspects of the disclosure. It is apparent, however, that various embodiments may be practiced without these specific details or with one or more equivalent arrangements.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there may be no intervening elements or layers present. The term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.”

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” “including,” “have,” “has,” and “having” when used in this specification, specify the presence of stated features, integers, steps, operations, elements, components, and/or groups thereof, but do not preclude the presence or addition of one or more other features, integers, steps, operations, elements, components, and/or groups thereof. “About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

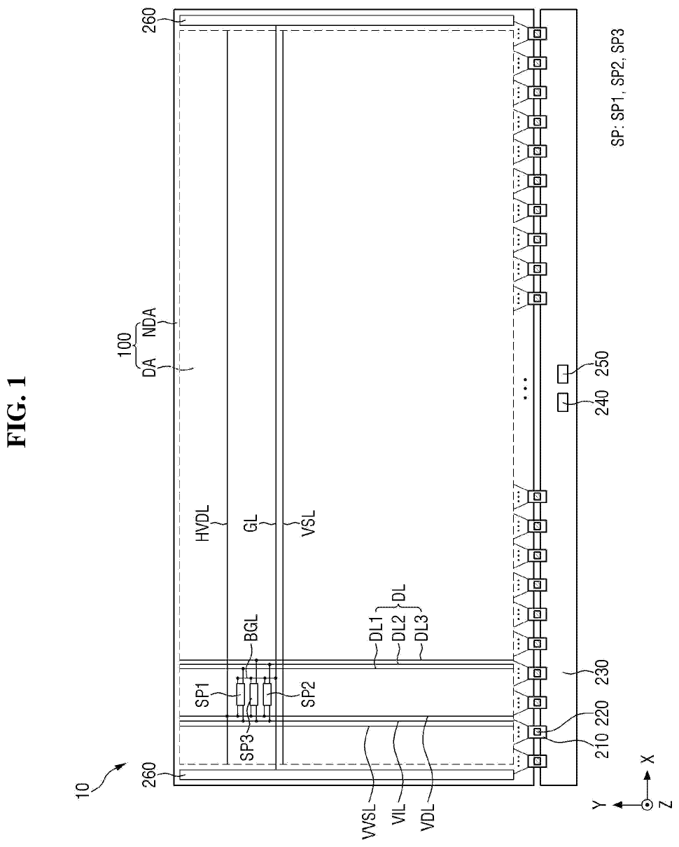

FIG. 1 is a schematic plan view showing a display device according to an embodiment of the disclosure.

As used herein, the terms “above,” “top” and “upper surface” may refer to the upper side of the display device, i.e., the side indicated by the arrow of the z-axis direction, whereas the terms “below,” “bottom” and “lower surface” may refer to the lower side of the display device, i.e., the opposite side in the z-axis direction. As used herein, the terms “left side,” “right side,” “upper side” and “lower side” may indicate relative positions of the display device in a plan view. For example, the “left side” may refer to the opposite side indicated by the arrow of the x-axis, the “right side” may refer to the side indicated by the arrow of the x-axis, the “upper side” may refer to the side indicated by the arrow of the y-axis, and the “lower side” may refer to the opposite side indicated by the arrow of the y-axis.

Referring to FIG. 1, the display device 10 is for displaying video or still image. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device, and a ultra mobile PC (UMPC), as well as the display screen of various products such as a television, a laptop computer, a monitor, a billboard, and the Internet of Things device.

The display device 10 may include a display panel 100, flexible films 210, display drivers 220, a circuit board 230, a timing controller 240, a power supply unit 250, and a gate driver 260.

The display panel 100 may have a rectangular shape in a plan view. For example, the display panel 100 may have a rectangular shape having longer sides in the first direction (x-axis direction) and shorter sides in the second direction (y-axis direction) in a plan view. The corners where the shorter sides in the first direction (x-axis direction) meet the longer sides in the second direction (y-axis direction) may be a right angle or may be rounded with a predetermined or selected curvature. The shape of the display panel 100 in a plan view is not limited to a rectangular shape, but may be formed in a different polygonal shape, a circular shape, or an elliptical shape. For example, the display panel 100 may be formed flat, but the disclosure is not limited thereto. As another example, the display panel 100 may be formed to bend with a predetermined or selected curvature.

The display panel 100 may include a display area DA and a non-display area NDA.

The display area DA displays images therein and may be defined as a central area of the display panel 100. The display area DA may include pixels SP, gate lines GL, data lines DL, initialization voltage lines VIL, first voltage lines VDL, horizontal voltage lines HVDL, vertical voltage lines VVSL, and second voltage lines VSL. The pixels SP may be formed in pixel areas that are intersections of the data lines DL and the gate lines GL, respectively. The pixels SP may include first to third pixels SP1, SP2 and SP3. Each of the first to third sub-pixels SP1, SP2 and SP3 may be connected to a gate line GL and a data line DL. Each of the first to third pixels SP1, SP2 and SP3 may be defined as the minimum unit area that emits light.

Each of the first to third pixels SP1, SP2 and SP3 may include an organic light-emitting diode including an organic light-emitting layer, a quantum-dot light-emitting diode (LED) including a quantum-dot light-emitting layer, a micro LED, or an inorganic LED including an inorganic semiconductor.

The first pixel SP1 may emit light of a first color or red light, the second pixel SP2 may emit light of a second color or green light, and the third pixel SP3 may emit light of a third color or blue light. The pixel circuit of the first pixel SP1, the pixel circuit of the third pixel SP3 and the pixel circuit of the second pixel SP2 may be arranged in the direction opposite to the second direction (y-axis direction). It should be understood, however, that the disclosure is not limited thereto.

The gate lines GL may be extended in the first direction (x-axis direction) and may be spaced apart from one another in the second direction (x-axis direction). The gate lines GL may receive gate signals from the gate driver 260 to provide the gate signals to auxiliary gate lines BGL. The auxiliary gate lines BGL may be extended from the gate lines GL to provide gate signals to the first to third sub-pixels SP1, SP2 and SP3.

The data lines DL may be extended in the second direction (y-axis direction) and may be spaced apart from each other in the first direction (x-axis direction). The data lines DL may include first to third data lines DL1, DL2 and DL3. The first to third data lines DL1, DL2 and DL3 may supply data voltage to each of the first to third pixels SP1, SP2 and SP3.

The initialization voltage lines VIL may be extended in the second direction (y-axis direction) and may be spaced apart from each other in the first direction (x-axis direction). The initialization voltage lines VIL may supply the initialization voltage received from the display driver 220 to the pixel circuit of each of the first to third sub-pixels SP1, SP2 and SP3. The initialization voltage line VIL may receive a sensing signal from the pixel circuit of each of the first to third pixels SP1, SP2 and SP3 and may supply the sensing signal to the display drivers 220.

The first voltage lines VDL may be extended in the second direction (y-axis direction) and may be spaced apart from one another in the first direction (x-axis direction). The first voltage line VDL may supply a driving voltage or a high-level voltage received from the power supply 250 to the first to third pixels SP1, SP2 and SP3.

The horizontal voltage lines HVDL may be extended in the first direction (x-axis direction) and may be spaced apart from one another in the second direction (x-axis direction). The horizontal voltage lines HVDL may be connected to the first voltage lines VDL. The horizontal voltage lines HVDL may receive the driving voltage or high-level voltage from the first voltage lines VDL.

The vertical voltage line VVSL may be extended in the second direction (y-axis direction) and may be spaced apart from each other in the first direction (x-axis direction). The vertical voltage line VVSL may be connected to the second voltage lines VSL. The vertical voltage line VVSL may supply the low-level voltage received from the power supply 250 to the second voltage lines VSL.

The second voltage lines VSL may be extended in the first direction (x-axis direction), and may be spaced apart from each other in the second direction (y-axis direction). The second voltage lines VSL may supply a low-level voltage to the first to third sub-pixels SP1, SP2 and SP3.

The connection relationship of the pixels SP, the gate lines GL, the data lines DL, the initialization voltage lines VIL, the first voltage lines VDL and the second voltage lines VSL may be altered depending on the number and arrangement of the pixels SP.

The non-display area NDA may be defined as the remaining area of the display panel 100 except the display area DA. For example, the non-display area NDA may include fan-out lines connecting the data lines DL, the initialization voltage lines VIL, the first voltage lines VDL and the vertical voltage line VVSL with the data drivers 220, a gate driver 260, and pads (not shown) connected to the flexible films 210.

The flexible films 210 may be connected to the pads disposed on the lower side of the non-display area NDA. The input terminals disposed on a side of the flexible films 210 may be attached to the circuit board 230 via a film attaching process, and the output terminals provided on another side of the flexible films 210 may be attached to the pads via a film attaching process. For example, each of the flexible films 210 may be bent, like a tape carrier package and a chip on film. The flexible films 210 may be bent so that they are disposed under the display panel 100 to reduce the bezel area of the display device 10.

The display drivers 220 may be mounted on the flexible films 210, respectively. For example, the display drivers 220 may be implemented as integrated circuits (IC). The display drivers 220 may receive digital video data and a data control signal from the timing controller 240, and may convert the digital video data into an analog data voltage in response to the data control signal to send it to the data lines DL through the fan-out lines.

The circuit board 230 may support the timing controller 240 and the power supply 250, and may provide signals and voltages to the display drivers 220. For example, the circuit board 230 may provide a signal provided from the timing controller 240 and supply voltages applied from the power supply unit 250 to the flexible films 210 and the data drivers 220 to drive the pixels to display images. To this end, signal lines and voltage lines may be disposed on the circuit board 230.

The timing controller 240 may be mounted on the circuit board 230 and may receive image data and a timing synchronization signal supplied from a display driving system or a graphic device through a user connector provided on the circuit board 230. The timing controller 240 may generate digital video data by coordinating the image data appropriately for the pixel arrangement structure in response to a timing synchronization signal, and may supply the generated digital video data to the display driver 220. The timing controller 240 may generate a data control signal and a gate control signal based on the timing synchronization signal. The timing controller 240 may control the timing of applying the data voltage of the display driver 220 based on the data control signal, and may control the timing of providing the gate signal of the display driver 260 based on the gate control signal.

The power supply unit 250 may be disposed on the circuit board 230 to apply a supply voltage to the flexible films 210 and the display driver 220. For example, the power supply unit 250 may generate a driving voltage or a high-level voltage to supply it to the first voltage lines VDL, may generate a low-level voltage to supply it to the vertical voltage line VVSL, and may generate an initialization voltage to supply it to the initialization voltage lines.

The gate driver 260 may be disposed on the left side and the right side of the non-display area NDA. The gate driver 260 may generate a gate signal based on a gate control signal provided from the timing controller 240. The gate control signal may include, but is not limited to, a start signal, a clock signal, and a supply voltage. The gate driver 260 may provide gate signals to the gate lines GL in a predetermined or selected order.

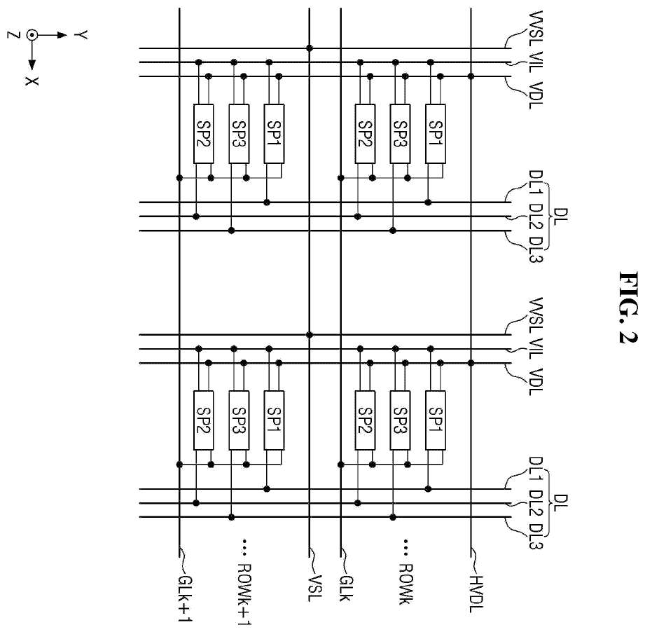

FIG. 2 is a schematic view showing pixels and lines of a display device according to an embodiment.

Referring to FIG. 2, a pixel SP may include first to third pixels SP1, SP2 and SP3. The pixel circuit of the first pixel SP1, the pixel circuit of the third pixel SP3 and the pixel circuit of the second pixel SP2 may be arranged in the direction opposite to the second direction (y-axis direction). It should be understood, however, that the disclosure is not limited thereto.

Each of the first to third sub-pixels SP1, SP2 and SP3 may be connected to the first voltage lines VDL, the initialization voltage lines VIL, the gate lines GL and the data lines DL.

The first voltage lines VDL may be extended in the second direction (y-axis direction). The first voltage lines VDL may be disposed on the left side of the pixel circuits of the first to third pixels SP1, SP2 and SP3. The first voltage lines VDL may supply a driving voltage or a high-level voltage to transistors of each of the first to third pixels SP1, SP2 and SP3.

The horizontal voltage lines HVDL may be extended in the first direction (x-axis direction). The horizontal voltage lines HVDL may be disposed on the upper side of the pixel circuit of the first pixel SP1 disposed in the k^{th} row ROWk, where k is a positive integer. The horizontal voltage lines HVDL may be connected to the first voltage lines VDL. The horizontal voltage lines HVDL may receive the driving voltage or high-level voltage from the first voltage lines VDL.

The initialization voltage line VIL may be extended in the second direction (y-axis direction). The initialization voltage line VIL may be disposed on the left side of the first voltage line VDL. The initialization voltage line VIL may be disposed between the vertical voltage line VVSL and the first voltage line VDL. The initialization voltage line VIL may apply the initialization voltage to the pixel circuit of each of the first to third pixels SP1, SP2 and SP3. The initialization voltage line VIL may receive a sensing signal from the pixel circuit of each of the first to third pixels SP1, SP2 and SP3 and may supply the sensing signal to the display drivers 220.

The vertical voltage line VVSL may be extended in the second direction (y-axis direction). The vertical voltage line VVSL may be disposed on the left side of the initialization voltage line VIL. The vertical voltage line VVSL may be connected between the power supply unit 250 and the second voltage line VSL. The vertical voltage line VVSL may provide the low-level voltage applied from the power supply unit 250 to the second voltage line VSL.

A second voltage line VSL may be extended in the first direction (x-axis direction). The second voltage line VSL may be disposed on the upper side of the pixel circuit of the first pixel SP1 disposed in the (k+1)^{th} row ROW(k+1). The second voltage line VSL may supply the low-level voltage received from the vertical voltage line VVSL to the light-emitting element layer of the first to third pixels SP1, SP2 and SP3.

The gate lines GL may be extended in the first direction (x-axis direction). The gate lines GL may be disposed on the lower side of the pixel circuit of the second pixel SP2. The gate lines GL may provide the gate signals received from the gate driver 260 to the auxiliary gate lines BGL. For example, the k^{th} gate line GLk may provide gate signals to the pixels SP disposed in the k^{th} row ROWk, and the (k+1)^{th} gate line GL(k+1) may provide gate signals to the pixels SP disposed in the (k+1)^{th} row ROW(k+1).

The auxiliary gate lines BGL may be extended in the second direction (y-axis direction) from the gate lines GL. The auxiliary gate lines BGL may be disposed on the right side of the pixel circuits of the first to third pixels SP1, SP2 and SP3. The auxiliary gate lines BGL may supply the gate signals received from the gate lines GL to the pixel circuits of the first to third pixels SP1, SP2 and SP3.

The data lines DL may be extended in the second direction (y-axis direction). The data lines DL may supply data voltages to the pixels SP. The data lines DL may include first to third data lines DL1, DL2 and DL3.

A first data line DL1 may be extended in the second direction (y-axis direction). The first data line DL1 may be disposed on the right side of the auxiliary gate line BGL. The first data line DL1 may supply the data voltage received from the display driver 220 to the pixel circuit of the first pixel SP1.

The second data line DL2 may be extended in the second direction (y-axis direction). The second data line DL2 may be disposed on the right side of the first data line DL1. The second data line DL2 may supply the data voltage received from the display driver 220 to the pixel circuit of the second pixel SP2.

The third data line DL3 may be extended in the second direction (y-axis direction). The third data line DL3 may be disposed on the right side of the second data line DL2. The third data line DL3 may supply the data voltage received from the display driver 220 to the pixel circuit of the third pixel SP3.

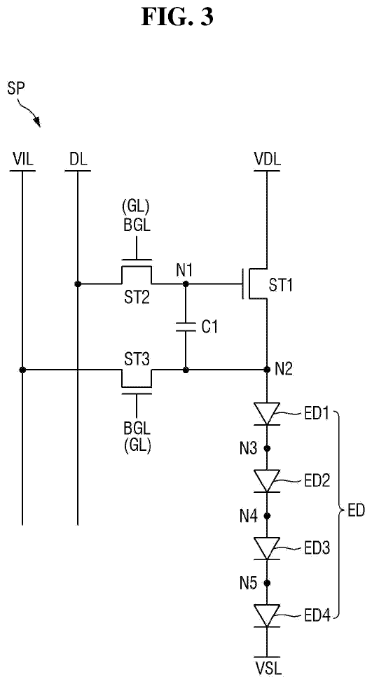

FIG. 3 is a schematic circuit diagram showing a pixel of a display device according to an embodiment of the disclosure.

Referring to FIG. 3, each of the pixels SP may be connected to a first voltage line VDL, a data line DL, an initialization voltage line VIL, a gate line GL, and a second voltage line VSL.

Each of the first to third pixels SP1, SP2 and SP3 may include first to third transistors ST1, ST2 and ST3, a first capacitor C1, and multiple light-emitting elements ED.

The first transistor ST1 may include a gate electrode, a drain electrode, and a source electrode. The gate electrode of the first transistor ST1 may be connected to a first node N1, the drain electrode thereof may be connected to the first voltage line VDL, and the source electrode thereof may be connected to a second node N2. The first transistor ST1 may control a drain-source current (or a driving current) based on a data voltage applied to the gate electrode.

The light-emitting elements ED may include first to fourth light-emitting elements ED1, ED2, ED3 and ED4. The first to fourth light-emitting elements ED1, ED2, ED3 and ED4 may be connected in series. The first to fourth light-emitting elements ED1, ED2, ED3 and ED4 may receive the driving current to emit light. The amount or the brightness of the light emitted from the light-emitting elements ED may be proportional to the magnitude of the driving current. The light-emitting element ED may be an organic light-emitting diode including an organic light-emitting layer, a quantum-dot LED including a quantum-dot light-emitting layer, a micro LED, or an inorganic LED including an inorganic semiconductor.

A first electrode of the first light-emitting element ED1 may be connected to the second node N2, and a second electrode of the first light-emitting element ED1 may be connected to a third node N3. The first electrode of the first light-emitting element ED1 may be connected to the source electrode of the first transistor ST1, the drain electrode of the third transistor ST3, and the second electrode of the first capacitor C1 through the second node N2. The second electrode of the first light-emitting element ED1 may be connected to the first electrode of the second light-emitting element ED2 through the third node N3.

A first electrode of the second light-emitting element ED2 may be connected to the third node N3, and a second electrode of the second light-emitting element ED2 may be connected to a fourth node N4. A first electrode of the third light-emitting element ED3 may be connected to the fourth node N4, and a second electrode of the third light-emitting element ED3 may be connected to a fifth node N5. A first electrode of the fourth light-emitting element ED4 may be connected to the fifth node N5, and a second electrode of the fourth light-emitting element ED4 may be connected to the second voltage line VSL.

The second transistor ST2 may be turned on by a gate signal from the gate line GL to electrically connect the data line DL with the first node N1, which is the gate electrode of the first transistor ST1. The second transistor ST2 may be turned on in response to the gate signal to apply data voltage to the first node N1. The gate electrode of the second transistor ST2 may be connected to the gate line GL, the drain electrode may be connected to the data line DL, and the source electrode may be connected to the first node N1. The source electrode of the second transistor ST2 may be connected to the gate electrode of the first transistor ST1 and the first capacitor electrode of the first capacitor C1 through the first node N1.

The third transistor ST3 may be turned on by a gate signal of a gate line GL to electrically connect the initialization voltage line VIL with the second node N2, which is the source electrode of the first transistor ST1. The third transistor ST3 may be turned on in response to the gate signal to apply the initialization voltage to the second node N2. The third transistor ST3 may be turned on in response to the gate signal to apply the sensing signal to the initialization voltage in VIL. The gate electrode of the third transistor ST3 may be connected to the gate line GL, the drain electrode may be connected to the second node N2, and the source electrode may be connected to the initialization voltage line VIL. The drain electrode of the third transistor ST3 may be connected to the source electrode of the first transistor ST1 through the second node N2, the second capacitor electrode of the first capacitor C1, and the first electrodes of the first light-emitting element ED1.

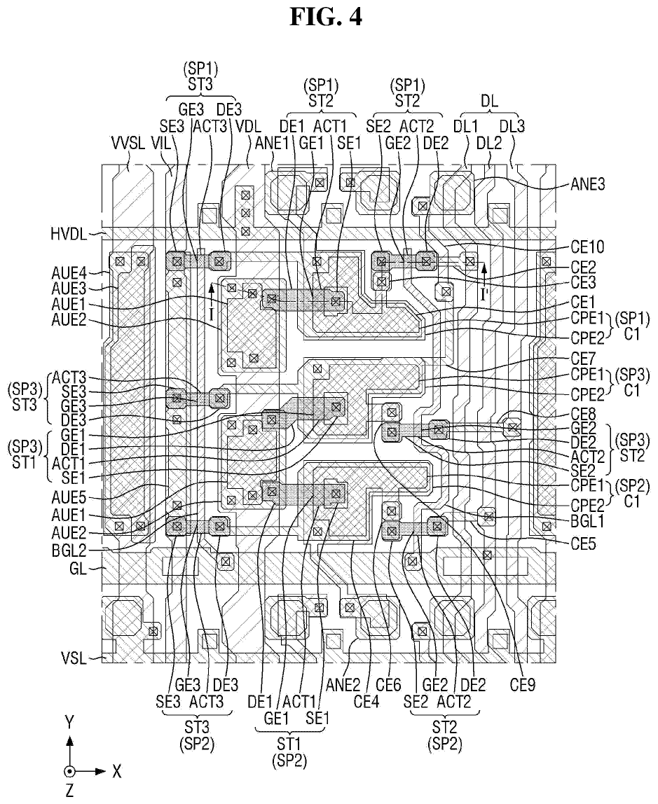

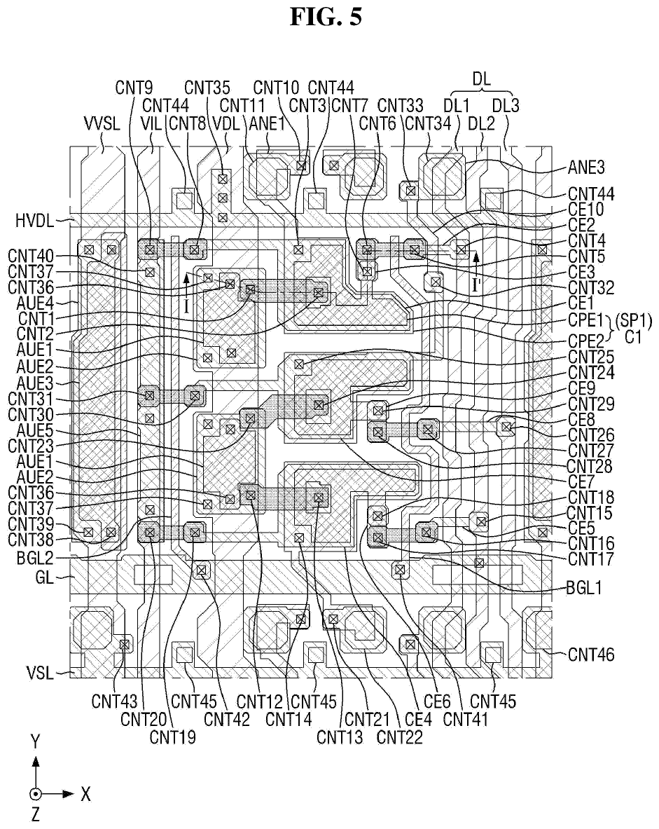

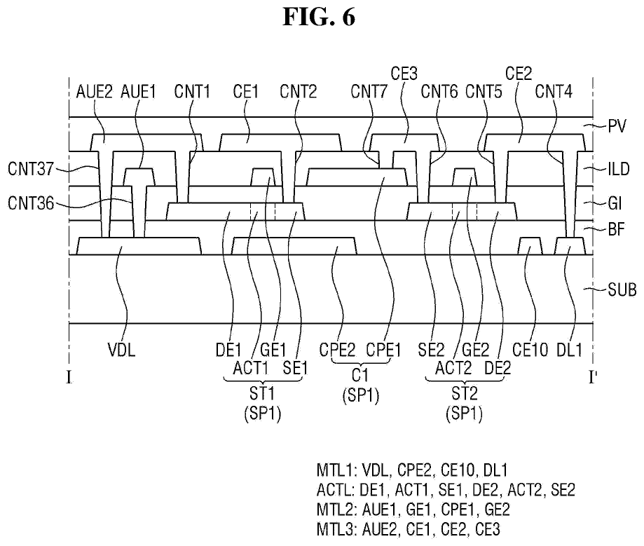

FIGS. 4 and 5 are schematic plan views showing a thin-film transistor layer of a display device according to an embodiment. FIG. 6 is a schematic cross-sectional view, taken along line I-I′ of FIGS. 4 and 5. FIGS. 4 and 5 are the same figure with different reference numerals.

Referring to FIGS. 4 to 6, the display area DA may include first to third pixels SP1, SP2 and SP3, first voltage lines VDL, horizontal voltage lines HVDL, initialization voltage lines VIL, gate lines GL, first and second auxiliary gate lines BGL, data lines DL, second voltage lines VSL, and vertical voltage lines VVSL.

The pixels SP may include first to third pixels SP1, SP2 and SP3. The pixel circuit of the first pixel SP1, the pixel circuit of the third pixel SP3 and the pixel circuit of the second pixel SP2 may be arranged in the direction opposite to the second direction (y-axis direction). It should be understood, however, that the disclosure is not limited thereto.

The first voltage line VDL may be disposed on a first metal layer MTL1 on the substrate SUB. The first voltage lines VDL may be disposed on the left side of the pixel circuits of the first to third pixels SP1, SP2 and SP3. The first voltage line VDL may overlap a first auxiliary electrode AUE1 of a second metal layer MTL2 and a second auxiliary electrode AUE2 of a third metal layer MTL3. The second metal layer MTL2 may be disposed on the gate insulator GI covering an active layer ACTL, and the third metal layer MTL3 may be disposed on an interlayer dielectric layer ILD covering the second metal layer MTL2. A protective layer PV may cover the third metal layer MTL3. The first auxiliary electrode AUE1 may be connected to the first voltage line VDL through multiple thirty-sixth contact holes CNT36. The second auxiliary electrode AUE2 may be connected to the first voltage line VDL through multiple thirty-seventh contact holes CNT37. The first voltage line VDL may be connected to the first and second auxiliary electrodes AUE1 and AUE2 to reduce line resistance.

The second auxiliary electrode AUE2 may be connected to the drain electrode DE1 of the first transistor ST1 of the first pixel SP1 through a first contact hole CNT1, the drain electrode DE1 of the first transistor ST1 of the second pixel SP2 through a twelfth contact hole CNT12, and the drain electrode DE1 of the first transistor ST1 of the third pixel SP3 through a twenty-third hole CNT23. Accordingly, the first voltage line VDL may supply a driving voltage to the first to third pixels SP1, SP2 and SP3 through the second auxiliary electrode AUE2.

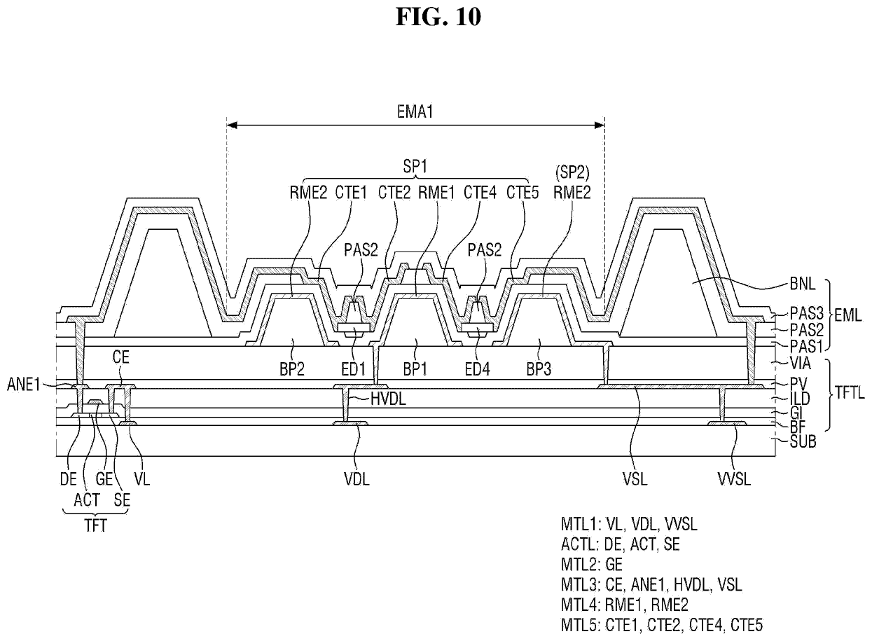

The horizontal voltage lines HVDL may be disposed on the third metal layer MTL3. The horizontal voltage line HVDL may be disposed on the upper side of the pixel circuit of the first pixel SP1. The horizontal voltage line HVDL may be connected to the first voltage line VDL through multiple thirty-fifth contact holes CNT35 to receive a driving voltage. The horizontal voltage lines HVDL may provide a driving voltage or a high-level voltage to a first electrode RME1 (see FIG. 10) of a fourth metal layer MTL4 (see FIG. 10) through multiple forty-fourth contact holes CNT44.

The initialization voltage line VIL may be disposed on the first metal layer MTL. The initialization voltage line VIL may be disposed on the left side of the first voltage line VDL. The initialization voltage line VIL may overlap a fifth auxiliary electrode AUE5 of the third metal layer MTL3. The fifth auxiliary electrode AUE5 may be connected to the initialization voltage line VIL through multiple fortieth contact holes CNT40. The initialization voltage line VIL may be connected to the fifth auxiliary electrode AUE5 to reduce line resistance.

The fifth auxiliary electrode AUE5 may be connected to the source electrode SE3 of the third transistor ST3 of the first pixel SP1 through a ninth contact hole CNT9, the source electrode SE3 of the third transistor ST3 of the second pixel SP2 through a twentieth contact hole CNT20, and the source electrode SE3 of the third transistor ST3 of the third pixel SP3 through a thirty-first contact hole CNT31. Accordingly, the initialization voltage line VIL may supply an initialization voltage to the third transistor ST3 of each of the first to third pixels SP1, SP2 and SP3 through the fifth auxiliary electrode AUE5, and may receive a sensing signal from the third transistor ST3.

The vertical voltage line VVSL may be disposed on the first metal layer MTL1. The vertical voltage line VVSL may be disposed on the left side of the initialization voltage line VIL. The vertical voltage line VVSL may overlap a third auxiliary electrode AUE3 of the second metal layer MTL2 and a fourth auxiliary electrode AUE4 of the third metal layer MTL3. The third auxiliary electrode AUE3 may be connected to the vertical voltage line VVSL through multiple thirty-eighth contact holes CNT38. The fourth auxiliary electrode AUE4 may be connected to the vertical voltage line VVSL through multiple thirty-ninth contact holes CNT39. The vertical voltage line VVSL may be connected to the third and fourth auxiliary electrodes AUE3 and AUE4 to reduce line resistance. The vertical voltage line VVSL may be connected to the second voltage line VSL through a forty-third contact hole CNT43. The vertical voltage line VVSL may provide a low-level voltage to the second voltage line VSL.

The second voltage line VSL may be disposed in the third metal layer MTL3. The second voltage line VSL may be disposed on the lower side of the gate line GL. The second voltage line VSL may provide a low-level voltage to the second electrode RME2 (see FIG. 10) of the fourth metal layer MTL4 (see FIG. 10) through multiple forty-fifth contact holes CNT45. The second voltage line VSL may provide a low-level voltage to a fifth contact electrode CTE5 (see FIG. 10) of a fifth metal layer MTL5 (see FIG. 10) through a forty-sixth contact holes CNT46.

The gate line GL may be disposed in the third metal layer MTL3. The gate line GL may be disposed on the lower side of the pixel circuit of the second pixel SP2. The gate line GL may be connected to a first auxiliary gate line BGL1 through a forty-first contact hole CNT41 and connected to a second auxiliary gate line BGL2 through a forty-second contact hole CNT42. The gate line GL may supply the gate signal received from the gate driver 260 to each of the first and second auxiliary gate lines BGL1 and BGL2. Accordingly, the first and second auxiliary gate lines BGL1 and BGL2 may provide the same gate signal to the pixel circuits of the first to third pixels SP1, SP2 and SP3.

The first auxiliary gate line BGL1 may be disposed in the second metal layer MTL2. The first auxiliary gate line BGL1 may be extended in the second direction (y-axis direction) from the gate line GL. The first auxiliary gate line BGL1 may be disposed on the right side of the pixel circuits of the first to third pixels SP1, SP2 and SP3. The first auxiliary gate line BGL1 may provide the gate signals received from the gate lines GL to the second transistor ST2 of each of the first to third pixels SP1, SP2 and SP3.

The second auxiliary gate line BGL2 may be disposed in the second metal layer MTL2. The second auxiliary gate line BGL2 may be extended in the second direction (y-axis direction) from the gate line GL. The second auxiliary gate line BGL2 may be disposed between the initialization voltage line VIL and the first voltage line VDL. The second auxiliary gate line BGL2 may provide the gate signals received from the gate lines GL to the third transistor ST3 of each of the first to third pixels SP1, SP2 and SP3.

The first data line DL1 may be disposed on the first metal layer MTL1. The first data line DL1 may be disposed on the right side of the first auxiliary gate line BGL1. A second connection electrode CE2 of the third metal layer MTL3 may be connected to the first data line DL1 through a fourth contact hole CNT4 and may be connected to the drain electrode DE2 of the second transistor ST2 of the first pixel SP1 through a fifth contact hole CNT5. Accordingly, the first data line DL1 may supply a data voltage to the second transistor ST2 of the first pixel SP1 through the second connection electrode CE2.

The second data line DL2 may be disposed on the first metal layer MTL1. The second data line DL2 may be disposed on the right side of the first data line DL1. A fifth connection electrode CE5 of the third metal layer MTL3 may be connected to the second data line DL2 through a fifteenth contact hole CNT15 and may be connected to the drain electrode DE2 of the second transistor ST2 of the second pixel SP2 through a sixteenth contact hole CNT16. Accordingly, the second data line DL2 may supply a data voltage to the second transistor ST2 of the second pixel SP2 through the fifth connection electrode CE5.

The third data line DL3 may be disposed on the first metal layer MTL1. The third data line DL3 may be disposed on the right side of the second data line DL2. An eighth connection electrode CE8 of the third metal layer MTL3 may be connected to the third data line DL3 through a twenty-sixth contact hole CNT26 and may be connected to the drain electrode DE2 of the second transistor ST2 of the third transistor SP3 through a twenty-seventh contact hole CNT27. Accordingly, the third data line DL3 may supply a data voltage to the second transistor ST2 of the third pixel SP3 through the eighth connection electrode CE8.

The pixel circuit of the first pixel SP1 may include the first to third transistors ST1, ST2 and ST3. The first transistor ST1 of the first pixel SP1 may include an active area ACT1, a gate electrode GE1, a drain electrode DE1, and a source electrode SE1. The active region ACT1 of the first transistor ST1 may be disposed in the active layer ACTL, and may overlap the gate electrode GE1 of the first transistor ST1. The active layer ACTL may be disposed on the buffer layer BF covering the first metal layer MTL1.

The gate electrode GE1 of the first transistor ST1 may be disposed in the second metal layer MTL2. The gate electrode GE1 of the first transistor ST1 may be a part of the first capacitor electrode CPE1 of the first capacitor C1.

The drain electrode DE1 and the source electrode SE1 of the first transistor ST1 may be formed into a conductor by heat-treating the active layer ACTL. The drain electrode DE1 and the source electrode SE1 may be made conductive as an n-type semiconductor, but the disclosure is not limited thereto. The drain electrode DE1 of the first transistor ST1 may be electrically connected to the first voltage line VDL through the second auxiliary electrode AUE2. The drain electrode DE1 of the first transistor ST1 may receive a driving voltage from the first voltage line VDL.

The source electrode SE1 of the first transistor ST1 may be connected to a first connection electrode CE1 through a second contact hole CNT2. The first connection electrode CE1 may be connected to a second capacitor electrode CPE2 of the first metal layer MTL1 through a third contact hole CNT3. Accordingly, the first capacitor C1 may be formed between the first capacitor electrode CPE1 and the second capacitor electrode CPE2 as well as between the first capacitor electrode CPE1 and the first connection electrode CE1.

The first anode connection electrode ANE1 may be disposed on the third metal layer MTL3. The first anode connection electrode ANE1 may be connected to an extended part of the second capacitor electrode CPE2 through a tenth contact hole CNT10, and may be electrically connected to the light-emitting elements ED of the first pixel SP1 through an eleventh contact hole CNT11. Accordingly, the first anode connection electrode ANE1 may supply the driving current received from the pixel circuit of the first pixel SP1 to the light-emitting elements ED.

The second transistor ST2 of the first pixel SP1 may include an active area ACT2, a gate electrode GE2, a drain electrode DE2 and a source electrode SE2. The active area ACT2 of the second transistor ST2 may be disposed in the active layer ACTL, and may overlap the gate electrode GE2 of the second transistor ST2.

The gate electrode GE2 of the second transistor ST2 may be disposed in the second metal layer MTL2. The gate electrode GE2 of the second transistor ST2 may be a part of the first auxiliary gate line BGL1.

The drain electrode DE2 and the source electrode SE2 of the second transistor ST2 may be formed into a conductor by heat-treating the active layer ACTL. The drain electrode DE2 of the second transistor ST2 may be electrically connected to the first data line DL1 through the second connection electrode CE2. The second connection electrode CE2 of the third metal layer MTL3 may be connected to the first data line DL1 through the fourth contact hole CNT4 and may be connected to the drain electrode DE2 of the second transistor ST2 of the first pixel SP1 through the fifth contact hole CNT5. Accordingly, the first data line DL1 may supply a data voltage to the second transistor ST2 of the first pixel SP1 through the second connection electrode CE2.

The source electrode SE2 of the second transistor ST2 may be electrically connected to the first capacitor electrode CPE1 of the first capacitor C1 through a third connection electrode CE3. The third connection electrode CE3 of the third metal layer MTL3 may be connected to the source electrode SE2 of the second transistor ST2 through a sixth contact hole CNT6, and may be connected to the first capacitor electrode CPE1 of the first capacitor C1 through a seventh contact hole CNT7.

The third transistor ST3 of the first pixel SP1 may include an active area ACT3, a gate electrode GE3, a drain electrode DE3 and a source electrode SE3. The active area ACT3 of the third transistor ST3 may be disposed in the active layer ACTL, and may overlap the gate electrode GE3 of the third transistor ST3.

The gate electrode GE3 of the third transistor ST3 may be disposed at the second metal layer MTL2. The gate electrode GE3 of the third transistor ST3 may be a part of the second auxiliary gate line BGL2.

The drain electrode DE3 and the source electrode SE3 of the third transistor ST3 may be formed into a conductor by heat-treating the active layer ACTL. The drain electrode D3 of the third transistor ST3 may be connected to an extended part of the first connection electrode CE1 through the eighth contact hole CNT8. The drain electrode DE3 of the third transistor ST3 may be electrically connected to the source electrode SE1 of the first transistor ST1 and the second capacitor electrode CPE2 of the first capacitor C1 through the first connection electrode CE1.

The source electrode SE3 of the third transistor ST3 may be electrically connected to the initialization voltage line VIL through the fifth auxiliary electrode AUE5. The fifth auxiliary electrode AUE5 may be connected to the source electrode SE3 of the third transistor ST2 through the ninth contact hole CNT9 and may be connected to the initialization voltage line VIL through the fortieth contact hole CNT40. The source electrode SE3 of the third transistor ST3 may receive an initialization voltage from the initialization voltage line VIL. The source electrode SE3 of the third transistor ST3 may supply a sensing signal to the initialization voltage line VIL.

The pixel circuit of the second pixel SP2 may include the first to third transistors ST1, ST2 and ST3. The first transistor ST1 of the second pixel SP2 may include an active area ACT1, a gate electrode GE1, a drain electrode DE1, and a source electrode SE1. The active region ACT1 of the first transistor ST1 may be disposed in the active layer ACTL, and may overlap the gate electrode GE1 of the first transistor ST1.

The gate electrode GE1 of the first transistor ST1 may be disposed in the second metal layer MTL2. The gate electrode GE1 of the first transistor ST1 may be a part of the first capacitor electrode CPE1 of the first capacitor C1.

The drain electrode DE1 and the source electrode SE1 of the first transistor ST1 may be formed into a conductor by heat-treating the active layer ACTL. The drain electrode DE1 and the source electrode SE1 may be made conductive as an n-type semiconductor, but the disclosure is not limited thereto. The drain electrode DE1 of the first transistor ST1 may be electrically connected to the first voltage line VDL through the second auxiliary electrode AUE2. The drain electrode DE1 of the first transistor ST1 may receive a driving voltage from the first voltage line VDL.

The source electrode SE1 of the first transistor ST1 may be connected to a fourth connection electrode CE4 through a thirteenth contact hole CNT13. The fourth connection electrode CE4 may be connected to a second capacitor electrode CPE2 of the first metal layer MTL1 through a fourteenth contact hole CNT14. Accordingly, the first capacitor C1 may be formed between the first capacitor electrode CPE1 and the second capacitor electrode CPE2 as well as between the first capacitor electrode CPE1 and the fourth connection electrode CE4.

The second anode connection electrode ANE2 may be disposed on the third metal layer MTL3. The second anode connection electrode ANE2 may be connected to an extended part of the second capacitor electrode CPE2 through a twenty-first contact hole CNT21, and may be electrically connected to the light-emitting elements ED of the second pixel SP2 through a twenty-second contact hole CNT22. Accordingly, the second anode connection electrode ANE2 may supply the driving current received from the pixel circuit of the second pixel SP2 to the light-emitting elements ED.

The second transistor ST2 of the second pixel SP2 may include an active area ACT2, a gate electrode GE2, a drain electrode DE2 and a source electrode SE2. The active area ACT2 of the second transistor ST2 may be disposed in the active layer ACTL, and may overlap the gate electrode GE2 of the second transistor ST2.

The gate electrode GE2 of the second transistor ST2 may be disposed in the second metal layer MTL2. The gate electrode GE2 of the second transistor ST2 may be a part of the first auxiliary gate line BGL1.

The drain electrode DE2 and the source electrode SE2 of the second transistor ST2 may be formed into a conductor by heat-treating the active layer ACTL. The drain electrode DE2 of the second transistor ST2 may be electrically connected to the second data line DL2 through the fifth connection electrode CE5. The fifth connection electrode CE5 of the third metal layer MTL3 may be connected to the second data line DL2 through the fifteenth contact hole CNT15 and may be connected to the drain electrode DE2 of the second transistor ST2 of the second pixel SP2 through the sixteenth contact hole CNT16. Accordingly, the second data line DL2 may supply a data voltage to the second transistor ST2 of the second pixel SP2 through the fifth connection electrode CE5.

The source electrode SE2 of the second transistor ST2 may be electrically connected to the first capacitor electrode CPE1 of the first capacitor C1 through the sixth connection electrode CE6. The sixth connection electrode CE6 of the third metal layer MTL3 may be connected to the source electrode SE2 of the second transistor ST2 through a seventieth contact hole CNT17, and may be connected to the first capacitor electrode CPE1 of the first capacitor C1 through an eighteenth contact hole CNT18.

The third transistor ST3 of the second pixel SP2 may include the active area ACT3, the gate electrode GE3, the drain electrode DE3 and the source electrode SE3. The active area ACT3 of the third transistor ST3 may be disposed in the active layer ACTL, and may overlap the gate electrode GE3 of the third transistor ST3.

The gate electrode GE3 of the third transistor ST3 may be disposed at the second metal layer MTL2. The gate electrode GE3 of the third transistor ST3 may be a part of the second auxiliary gate line BGL2.

The drain electrode DE3 and the source electrode SE3 of the third transistor ST3 may be formed into a conductor by heat-treating the active layer ACTL. The drain electrode D3 of the third transistor ST3 may be connected to an extended part of the fourth connection electrode CE4 through a nineteenth contact hole CNT19. The drain electrode DE3 of the third transistor ST3 may be electrically connected to the source electrode SE1 of the first transistor ST1 and the second capacitor electrode CPE2 of the first capacitor C1 through the fourth connection electrode CE4.

The source electrode SE3 of the third transistor ST3 may be electrically connected to the initialization voltage line VIL through the fifth auxiliary electrode AUE5. The fifth auxiliary electrode AUE5 may be connected to the source electrode SE3 of the third transistor ST3 through the twentieth contact hole CNT20 and may be connected to the initialization voltage line VIL through the fortieth contact hole CNT40. The source electrode SE3 of the third transistor ST3 may receive an initialization voltage from the initialization voltage line VIL. The source electrode SE3 of the third transistor ST3 may supply a sensing signal to the initialization voltage line VIL.

The pixel circuit of the third pixel SP3 may include the first to third transistors ST1, ST2 and ST3. The first transistor ST1 of the third pixel SP3 may include the active area ACT1, the gate electrode GE1, the drain electrode DE1 and the source electrode SE1. The active region ACT1 of the first transistor ST1 may be disposed in the active layer ACTL, and may overlap the gate electrode GE1 of the first transistor ST1.

The gate electrode GE1 of the first transistor ST1 may be disposed in the second metal layer MTL2. The gate electrode GE1 of the first transistor ST1 may be a part of the first capacitor electrode CPE1 of the first capacitor C1.

The drain electrode DE1 and the source electrode SE1 of the first transistor ST1 may be formed into a conductor by heat-treating the active layer ACTL. The drain electrode DE1 and the source electrode SE1 may be made conductive as an n-type semiconductor, but the disclosure is not limited thereto. The drain electrode DE1 of the first transistor ST1 may be electrically connected to the first voltage line VDL through the second auxiliary electrode AUE2. The drain electrode DE1 of the first transistor ST1 may receive a driving voltage from the first voltage line VDL.

The source electrode SE1 of the first transistor ST1 may be connected to the seventh connection electrode CE7 through the twenty-fourth contact hole CNT24. The seventh connection electrode CE7 may be connected to the second capacitor electrode CPE2 of the first metal layer MTL1 through a twenty-fifth contact hole CNT25. Accordingly, the first capacitor C1 may be formed between the first capacitor electrode CPE1 and the second capacitor electrode CPE2 as well as between the first capacitor electrode CPE1 and the seventh connection electrode CE7.

The tenth connection electrode CE10 may be disposed on the first metal layer MTL1. The tenth connection electrode CE10 may electrically connect a first extended part of the seventh connection electrode CE7 with the third anode connection electrode ANE3. The tenth connection electrode CE10 may be connected to the first extended part of the seventh connection electrode CE7 through a thirty-second hole CNT32, and may be connected to the third anode connection electrode ANE3 through a thirty-third contact hole CNT33.

The third anode connection electrode ANE3 may be disposed in the third metal layer MTL3. The third anode connection electrode ANE3 may be electrically connected to the light-emitting elements ED of the third pixels SP3 through a thirty-fourth contact hole CNT34. Accordingly, the third anode connection electrode ANE3 may supply the driving current received from the pixel circuit of the third pixel SP3 to the light-emitting elements ED.

The second transistor ST2 of the third pixel SP3 may include the active area ACT2, the gate electrode GE2, the drain electrode DE2 and the source electrode SE2. The active area ACT2 of the second transistor ST2 may be disposed in the active layer ACTL, and may overlap the gate electrode GE2 of the second transistor ST2.

The gate electrode GE2 of the second transistor ST2 may be disposed in the second metal layer MTL2. The gate electrode GE2 of the second transistor ST2 may be a part of the first auxiliary gate line BGL1.

The drain electrode DE2 and the source electrode SE2 of the second transistor ST2 may be formed into a conductor by heat-treating the active layer ACTL. The drain electrode DE2 of the second transistor ST2 may be electrically connected to the third data line DL3 through the eighth connection electrode CE8. An eighth connection electrode CE8 of the third metal layer MTL3 may be connected to the third data line DL3 through the twenty-sixth contact hole CNT26 and may be connected to the drain electrode DE2 of the second transistor ST2 of the third transistor SP3 through the twenty-seventh contact hole CNT27. Accordingly, the third data line DL3 may supply a data voltage to the second transistor ST2 of the third pixel SP3 through the eighth connection electrode CE8.

The source electrode SE2 of the second transistor ST2 may be electrically connected to the first capacitor electrode CPE1 of the first capacitor C1 through a ninth connection electrode CE9. The ninth connection electrode CE9 of the third metal layer MTL3 may be connected to the source electrode SE2 of the second transistor ST2 through a twenty-eighth contact hole CNT28, and may be connected to the first capacitor electrode CPE1 of the first capacitor C1 through a twenty-ninth contact hole CNT29.

The third transistor ST3 of the third pixel SP3 may include the active area ACT3, the gate electrode GE3, the drain electrode DE3 and the source electrode SE3. The active area ACT3 of the third transistor ST3 may be disposed in the active layer ACTL, and may overlap the gate electrode GE3 of the third transistor ST3.

The gate electrode GE3 of the third transistor ST3 may be disposed at the second metal layer MTL2. The gate electrode GE3 of the third transistor ST3 may be a part of the second auxiliary gate line BGL2.

The drain electrode DE3 and the source electrode SE3 of the third transistor ST3 may be formed into a conductor by heat-treating the active layer ACTL. The drain electrode D3 of the third transistor ST3 may be connected to a second extended part of the seventh connection electrode CE7 through a thirtieth contact hole CNT30. The drain electrode DE3 of the third transistor ST3 may be electrically connected to the source electrode SE1 of the first transistor ST1 and the second capacitor electrode CPE2 of the first capacitor C1 through the seventh connection electrode CE7.

The source electrode SE3 of the third transistor ST3 may be electrically connected to the initialization voltage line VIL through the fifth auxiliary electrode AUE5. The fifth auxiliary electrode AUE5 may be connected to the source electrode SE3 of the third transistor ST2 through the thirty-first contact hole CNT31 and may be connected to the initialization voltage line VIL through the fortieth contact hole CNT40. The source electrode SE3 of the third transistor ST3 may receive an initialization voltage from the initialization voltage line VIL. The source electrode SE3 of the third transistor ST3 may supply a sensing signal to the initialization voltage line VIL.

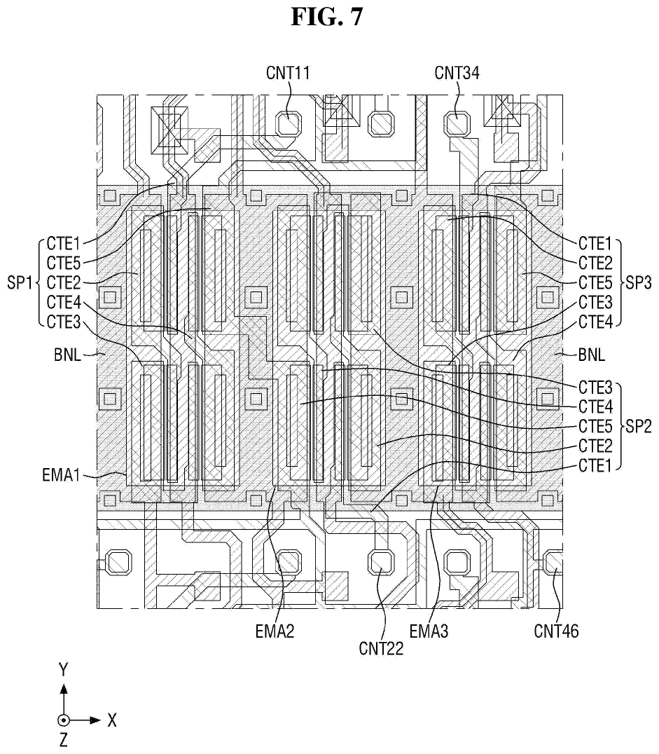

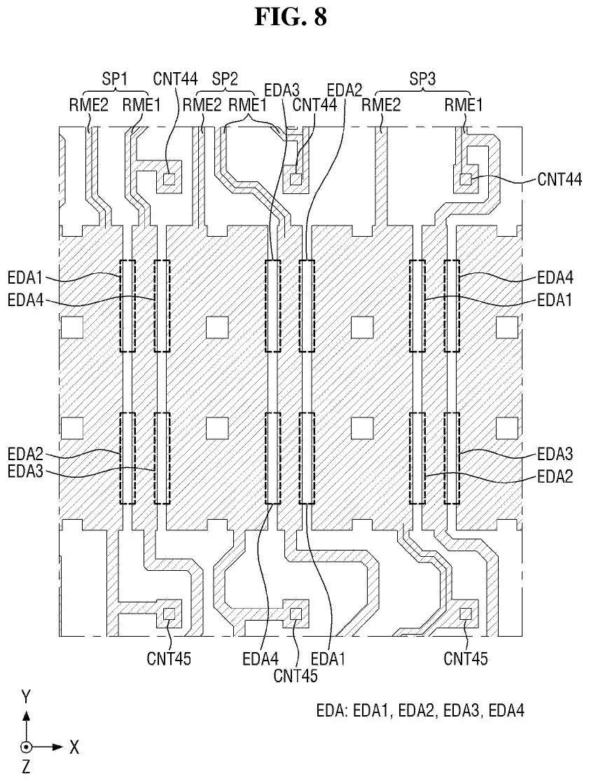

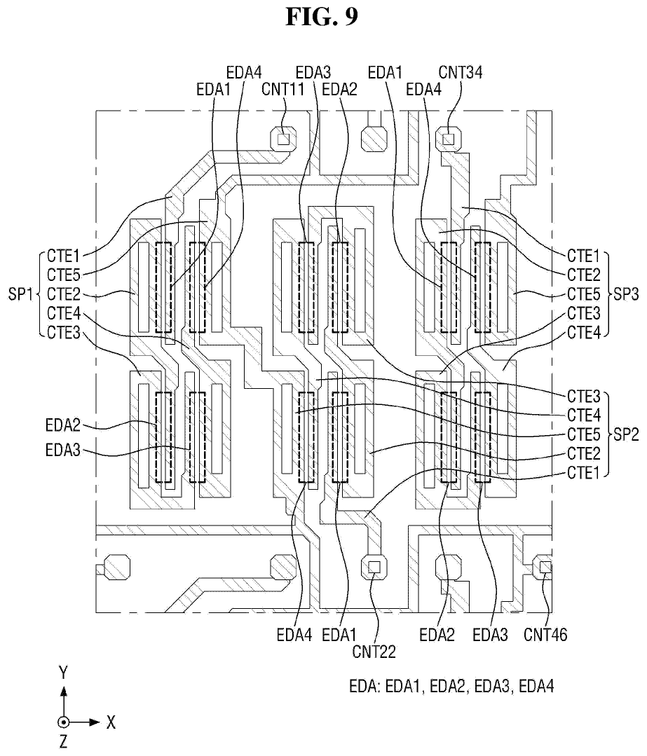

FIG. 7 is a schematic plan view showing an emission layer of a display device according to an embodiment of the disclosure. FIG. 8 is a schematic plan view showing a fourth metal layer of a display device according to an embodiment of the disclosure. FIG. 9 is a schematic plan view showing a fifth metal layer of a display device according to an embodiment of the disclosure. FIG. 10 is a schematic cross-sectional view of a display device according to an embodiment of the disclosure. The thin-film transistor layers of FIGS. 4 to 6 may correspond to the thin-film transistor layer TFTL of FIG. 10.

Referring to FIGS. 7 to 10, the display panel 100 may include a substrate SUB, a thin-film transistor layer TFTL, and an emission layer EML.

The thin-film transistor layer TFTL may be disposed on the substrate SUB. The thin-film transistor layer TFTL may include a first metal layer MTL1, a buffer layer BF, an active layer ACTL, a gate insulator GI, a second metal layer MTL2, an interlayer dielectric layer ILD, a third metal layer MTL3, a passivation layer PV, and a via layer VIA.

The first metal layer MTL1 may include a voltage line VL, a first voltage line VDL, and a vertical voltage line VVSL. The voltage line VL may be a first voltage line VDL, an initialized voltage line VIL, or a data line DL.

The active layer ACTL may include a drain electrode DE, an active region ACT and a source electrode SE of a thin-film transistor TFT, and the second metal layer MTL2 may include a gate electrode GE of the thin-film transistor TFT. The thin-film transistor TFT may be one of the first to third transistors ST1, ST2 and ST3 of FIGS. 4 to 6.

The third metal layer MTL3 may include a connection electrode CE, a first anode connection electrode ANE1, a horizontal voltage line HVDL, and a second voltage line VSL. The connection electrode CE may be one of the first to ninth connection electrodes CE1 to CE9 of FIGS. 4 to 6.

The emission layer EML may be disposed on the thin-film transistor layer TFTL. The emission layer EML may include first to third bank patterns BP1, BP2 and BP3, first and second electrodes RME1 and RME2, a first insulating layer PAS1, first to fourth light-emitting elements ED1, ED2, ED3 and ED4, a bank layer BNL, a second insulating layer PAS2, first to fifth contact electrodes CTE1, CTE2, CTE3, CTE4 and CTE5, and a third insulating layer PAS3.

The bank layer BNL may define first to third emission areas EMA1, EMA2 and EMA3. The light-emitting elements ED of the first pixel SP1 may be disposed in the first emission area EMA1, the light-emitting elements ED of the second pixel SP2 may be disposed in the second emission area EMA2, and the light-emitting elements ED of the third pixel SP3 may be disposed in the third emission area EMA3. FIG. 10 is a cross-sectional view schematically showing the first emission area EMA1.

The first to third bank patterns BP1, BP2 and BP3 may be extended in the second direction (y-axis direction) and may be spaced apart from one another in the first direction (x-axis direction). The first bank pattern BP1 may be disposed between the second and third bank patterns BP2 and BP3. The second bank pattern BP2 may be disposed on the left side of the first bank pattern BP1, and the third bank pattern BP3 may be disposed on the right side of the first bank pattern BP1. Each of the first to third bank patterns BP1, BP2 and BP3 may protrude upward (in the z-axis direction) on the via layer VIA. Each of the first to third bank patterns BP1, BP2 and BP3 may have inclined side surfaces. The first and second light-emitting elements ED1 and ED2 of the first pixel SP1 may be disposed between the first and second bank patterns BP1 and BP2 spaced apart from each other. The third and fourth light-emitting elements ED3 and ED4 of the first pixel SP1 may be disposed between the first and third bank patterns BP1 and BP3 spaced apart from each other. The first to third bank patterns BP1, BP2 and BP3 may be disposed as island-shaped patterns on the entire surface of the display area DA.

In FIG. 8, the first and second electrodes RME1 and RME2 of each of the first to third pixels SP1, SP2 and SP3 may be disposed in a fourth electrode layer MTL4. The maximum width of the second electrode RME2 in the first direction (x-axis direction) may be larger than the maximum width of the first electrode RME1 in the first direction (x-axis direction), but the disclosure is not limited thereto. The fourth electrode layer MTL4 may be disposed on the via layer VIA and the first to third bank patterns BP1, BP2 and BP3. The first and second electrodes RME1 and RME2 of each of the first to third pixels SP1, SP2 and SP3 may be extended in the second direction (y-axis direction). The first electrode RME1 of the first pixel SP1 may be disposed between the second electrode RME2 of the first pixel SP1 and the second electrode RME2 of the second pixel SP2. The first electrode RME1 of the second pixel SP2 may be disposed between the second electrode RME2 of the second pixel SP2 and the second electrode RME2 of the third pixel SP3. The first electrode RME1 of the third pixel SP3 may be disposed on the right side of the second electrode RME2 of the third pixel SP3.

Each of the first and second electrodes RME1 and RME2 may cover the upper surface and an inclined side surface of one of the first to third bank patterns BP1, BP2 and BP3. Accordingly, each of the first and second electrodes RME1 and RME2 may reflect the light emitted from the first to fourth light-emitting elements ED1, ED2, ED3 and ED4 upwardly (in the z-axis direction).

The first and second electrodes RME1 and RME2 may be alignment electrodes that align the first to fourth light-emitting elements ED1, ED2, ED3 and ED4 during the process of fabricating the display device 10. The first electrodes RME1 may be connected to the horizontal voltage line HVDL of the third metal layer MTL3 through the forty-fourth contact holes CNT44. The first electrode RME1 may receive a driving voltage or a high-level voltage from the horizontal voltage line HVDL. The second electrodes RME2 may be connected to the second voltage line VSL of the third metal layer MTL through the forty-fifth contact holes CNT45. The second electrode RME2 may receive a low-level voltage from the second voltage line VSL.

The plurality of light-emitting elements ED may be aligned between the first electrode RME1 and the second electrode RME2. The light-emitting elements ED may be disposed in light-emitting element areas EDA. Multiple first light-emitting elements ED1 may be disposed in a first light-emitting element area EDA1, multiple second light-emitting elements ED2 may be disposed in a second light-emitting element area EDA2, multiple third light-emitting elements ED3 may be disposed in a third light-emitting element area EDA3, and a plurality of fourth light-emitting elements ED4 may be disposed in a fourth light-emitting element area EDA4. The first and second light-emitting element areas EDA1 and EDA2 may be disposed between the first electrode RME1 of the first pixel SP1 and the second electrode RME2 of the first pixel SP1. The third and fourth light-emitting element areas EDA3 and EDA4 may be disposed between the first electrode RME1 of the first pixel SP1 and the second electrode RME2 of the second pixel SP2. The first insulating layer PAS1 may cover the first and second electrodes RME1 and RME2. The first to fourth light-emitting elements ED1, ED2, ED3 and ED4 may be insulated from the first and second electrodes RME1 and RME2 by the first insulating layer PAS1.

Each of the first and second electrodes RM1 and RM2 may receive an alignment signal, and an electric field may be formed between the first and second electrodes RM1 and RM2. For example, the first to fourth light-emitting elements ED1, ED2, ED3 and ED4 may be ejected onto the first and second electrodes RME1 and RME2 via an inkjet printing process. The first to fourth light-emitting elements ED1, ED2, ED3 and ED4 dispersed in the ink may be aligned by receiving a dielectrophoresis force by the electric field formed between the first and second electrodes RME1 and RME2. Accordingly, the first to fourth light-emitting elements ED1, ED2, ED3 and ED4 may be aligned in the second direction (y-axis direction) between the first and second electrodes RME1 and RME2.

In FIG. 9, the first to fifth contact electrodes CTE1, CTE2, CTE3, CTE4 and CTE5 of each of the first to third pixels SP1, SP2 and SP3 may be disposed in a fifth metal layer MTL5. The second insulating layer PAS2 may be disposed on the bank layer BNL, the first insulating layer PAS1, and the light-emitting elements ED. The third insulating layer PAS3 may cover the second insulating layer PAS2 and the first to fifth contact electrodes CTE1, CTE2, CTE3, CTE4 and CTE5. The second and third insulating layers PAS2 and PAS3 may insulate each of the first to fifth contact electrodes CTE1, CTE2, CTE3, CTE4 and CTE5. Each of the second to fifth contact electrodes CTE2, CTE3, CTE4 and CTE5 may include, but are not limited thereto, a void at the center.

A first contact electrode CTE1 of the first pixel SP1 may be disposed on the first electrode RME1 of the first pixel SP1, and may be connected to the first anode connection electrode ANE1 of the third metal layer MTL3 through the eleventh contact hole CNT11. The first contact electrode CTE1 may be connected between the first anode connection electrode ANE1 and first ends of the first light-emitting elements ED1. The first contact electrode CTE1 may receive the driving current passing through the first transistor ST1. The first contact electrode CTE1 may supply the driving current to the first light-emitting elements ED1 of the first pixel SP1. The first contact electrode CTE1 may correspond to the anode electrode of the first light-emitting elements ED1, but the disclosure is not limited thereto.

The second contact electrode CTE2 may be insulated from the first and second electrodes RME1 and RME2. A first portion of the second contact electrode CTE2 may be disposed on the second electrode RME2 of the first pixel SP1 and may be extended in the second direction (y-axis direction). The second portion of the second contact electrode CTE2 may be extended from the lower side of the first portion and may be disposed on the first electrode RME1 of the first pixel SP1.

The second contact electrode CTE2 may be connected between the second ends of the first light-emitting elements ED1 and the first ends of the second light-emitting elements ED2. The second contact electrode CNE2 may correspond to the third node N3 of FIG. 3. The second contact electrode CTE2 may correspond to the cathode electrode of each of the first light-emitting elements ED1, but the disclosure is not limited thereto. The second contact electrode CTE2 may correspond to the anode electrode of the second light-emitting elements ED2, but the disclosure is not limited thereto.

The third contact electrode CTE3 may be insulated from the first and second electrodes RME1 and RME2. A first portion of the third contact electrode CTE3 may be disposed on the second electrode RME2 of the first pixel SP1 and may be extended in the second direction (y-axis direction). The second portion of the third contact electrode CTE3 may be disposed on the first electrode RME1 of the first pixel SP1 and may be disposed on the right side of the first pixel SP1.

The third contact electrode CTE3 may be connected between the second ends of the second light-emitting elements ED2 and the first ends of the third light-emitting elements ED3. The third contact electrode CTE3 may correspond to the fourth node N4 of FIG. 3. The third contact electrode CTE3 may correspond to the cathode electrode of the second light-emitting elements ED2, but the disclosure is not limited thereto. The third contact electrode CTE3 may correspond to the anode electrode of the third light-emitting elements ED3, but the disclosure is not limited thereto.

The fourth contact electrode CTE4 may be insulated from the first and second electrodes RME1 and RME2. A first portion of the fourth contact electrode CTE4 may be disposed on the second electrode RME2 of the second pixel SP2 and may be extended in the second direction (y-axis direction). The second portion of the fourth contact electrode CTE4 may be extended from the upper side of the first portion and may be disposed on the first electrode RME1 of the first pixel SP1.

The fourth contact electrode CTE4 may be connected between the second ends of the third light-emitting elements ED3 and the first ends of the fourth light-emitting elements ED4. The fourth contact electrode CTE4 may correspond to the fifth node N5 of FIG. 4. The fourth contact electrode CTE4 may correspond to the cathode electrode of the third light-emitting elements ED3, but the disclosure is not limited thereto. The fourth contact electrode CTE4 may correspond to the anode electrode of the fourth light-emitting elements ED4, but the disclosure is not limited thereto.

A fifth contact electrode CTE5 may be connected between the second ends of the fourth light-emitting elements ED4 and the second voltage line VSL. The fifth contact electrode CTE5 may be disposed on the second electrode RME2 of the second pixel SP2 and may be extended in the second direction (y-axis direction). The fifth contact electrode CTE5 may be connected to the second voltage line VSL of the third metal layer MTL3 through the forty-sixth contact hole CNT46. The fifth contact electrode CTE5 may correspond to the cathode electrode of the fourth light-emitting elements ED4, but the disclosure is not limited thereto. The fifth contact electrode CTE5 may receive a low-level voltage through the second voltage line VSL. The fifth contact electrode CTE5 of the first to third pixels SP1, SP2 and SP3 may be formed as a single piece, but the disclosure is not limited thereto.

A first contact electrode CTE1 of the second pixel SP2 may be disposed on the first electrode RME1 of the second pixel SP2, and may be connected to the second anode connection electrode ANE2 of the third metal layer MTL3 through the twenty-second contact hole CNT22. The first contact electrode CTE1 may be connected between the second anode connection electrode ANE2 and first ends of the first light-emitting elements ED1. The first contact electrode CTE1 may receive the driving current passing through the first transistor ST1. The first contact electrode CTE1 may supply the driving current to the first light-emitting elements ED1 of the second pixel SP2.

A first contact electrode CTE1 of the third pixel SP3 may be disposed on the first electrode RME1 of the third pixel SP3, and may be connected to the third anode connection electrode ANE3 of the third metal layer MTL3 through the thirty-fourth contact hole CNT34. The first contact electrode CTE1 may be connected between the third anode connection electrode ANE3 and first ends of the first light-emitting elements ED1. The first contact electrode CTE1 may receive the driving current passing through the first transistor ST1. The first contact electrode CTE1 may supply the driving current to the first light-emitting elements ED1 of the third pixel SP3.

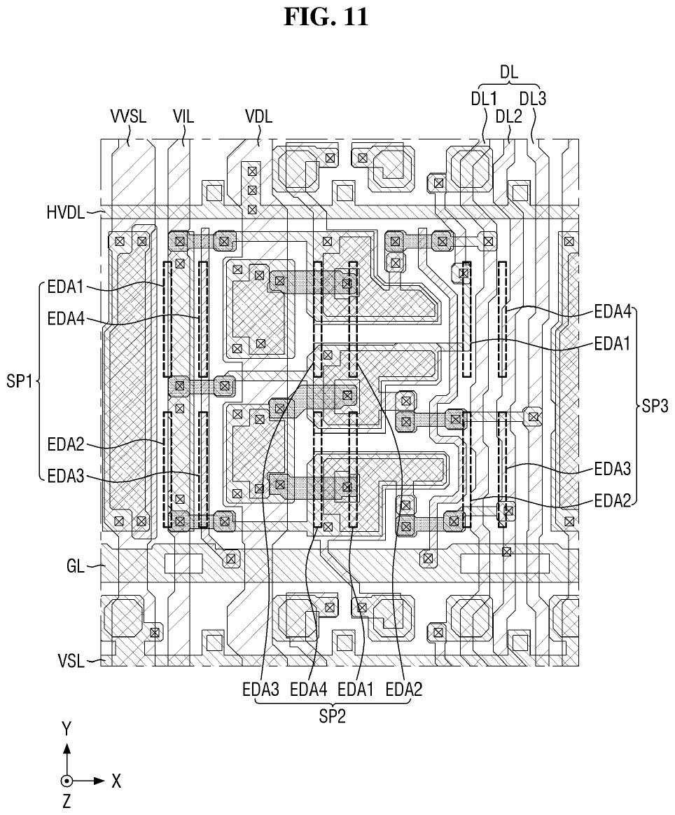

FIG. 11 is a schematic plan view showing a thin-film transistor layer and light-emitting element areas of a display device according to an embodiment.

Referring to FIG. 11, each of the first to third pixels SP1, SP2 and SP3 may include first to fourth light-emitting element areas EDA1, EDA2, EDA3 and EDA4. Multiple first light-emitting elements ED1 may be disposed in a first light-emitting element area EDA1, multiple second light-emitting elements ED2 may be disposed in a second light-emitting element area EDA2, multiple third light-emitting elements ED3 may be disposed in a third light-emitting element area EDA3, and multiple fourth light-emitting elements ED4 may be disposed in a fourth light-emitting element area EDA4.

The first to fourth light-emitting element areas EDA1, EDA2, EDA3 and EDA4 of the first pixel SP1 may overlap the initialization voltage line VIL and the second auxiliary gate line BGL2. The initialization voltage line VIL and the second auxiliary gate line BGL2 may not receive an alignment signal during the process of aligning the light-emitting elements ED. The first voltage line VDL may receive a first alignment signal to provide it to the first electrode RME1 during the process of aligning the light-emitting elements ED, and the vertical voltage line VVSL may receive a second alignment signal to provide it to the second electrode RME2. For example, the first and second light-emitting element areas EDA1 and EDA2 may be spaced apart from the vertical voltage line VVSL and the third and fourth auxiliary electrodes AUE3 and AUE4 by about 6 μm or more. The third and fourth light-emitting element areas EDA3 and EDA4 may be spaced apart from the first voltage line VDL and the first and second auxiliary electrodes AUE1 and AUE2 by about 8 μm or more. Accordingly, the light-emitting elements ED of the first pixel SP1 suppresses the influence of the first voltage line VDL and the vertical voltage line VVSL in the alignment process, so that the reliability of the display device 10 can be improved as they are readily aligned between the first and second electrodes RME1 and RME2.

The first to fourth light-emitting element areas EDA1, EDA2, EDA3 and EDA4 of the second pixel SP2 may overlap the first capacitor C1 of each of the first to third pixels SP1, SP2 and SP3. The first capacitor C1 of each of the first to third pixels SP1, SP2 and SP3 may not receive an alignment signal during the process of aligning the light-emitting elements ED. Accordingly, the light-emitting elements ED of the second pixel SP2 suppresses the influence of the alignment signal in the alignment process, so that the reliability of the display device 10 can be improved as they are readily aligned between the first and second electrodes RME1 and RME2.

The first to fourth light-emitting element areas EDA1, EDA2, EDA3 and EDA4 of the third pixel SP3 may overlap at least one of the first auxiliary gate line BGL1, and the first and second data lines DL1 and DL2. The first auxiliary gate line BGL1 and the first and second data lines DL1 and DL2 may not receive an alignment signal during the process of aligning the light-emitting elements ED. Accordingly, the light-emitting elements ED of the third pixel SP3 suppresses the influence of the alignment signal in the alignment process, so that the reliability of the display device 10 can be improved as they are readily aligned between the first and second electrodes RME1 and RME2.

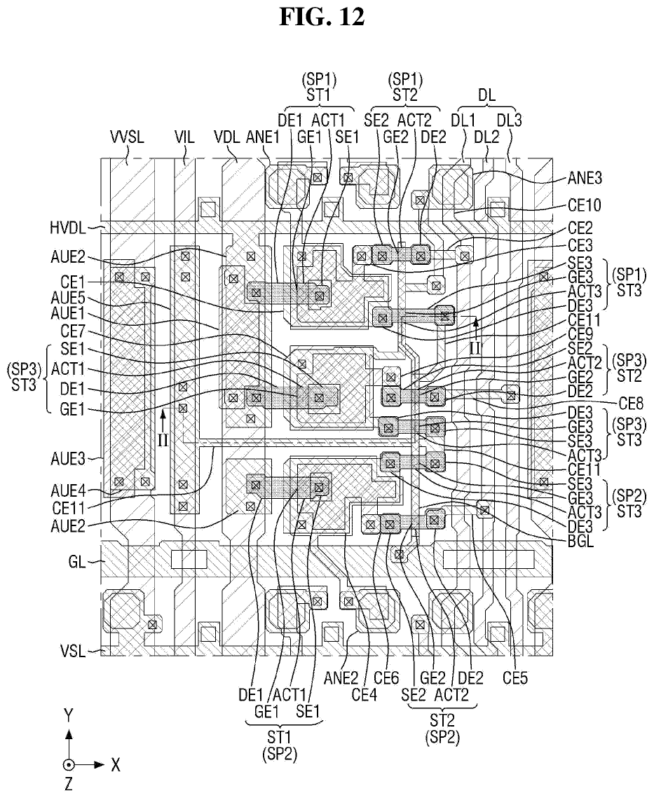

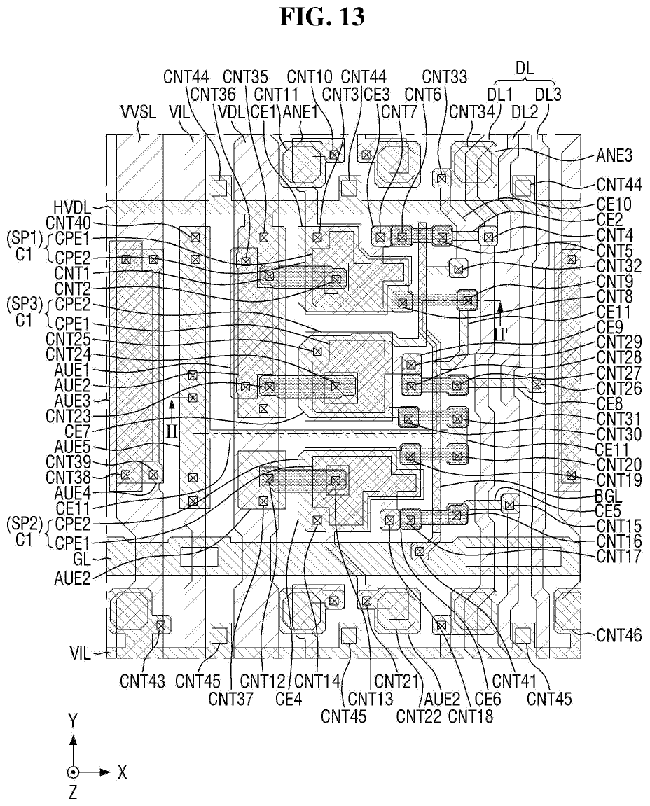

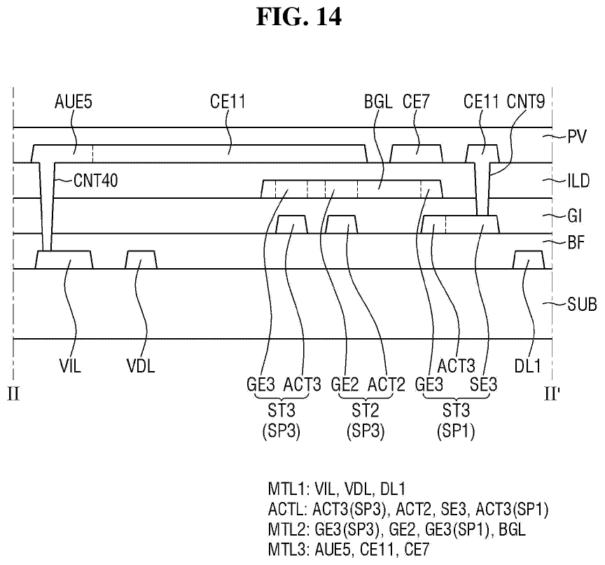

FIGS. 12 and 13 are schematic plan views showing a thin-film transistor layer of a display device according to another embodiment. FIG. 14 is a schematic cross-sectional view, taken along line II-II′ of FIGS. 12 and 13. FIGS. 12 and 13 are the same figure with different reference numerals.

Referring to FIGS. 12 to 14, the display area DA may include first to third pixels SP1, SP2 and SP3, first voltage lines VDL, horizontal voltage lines HVDL, initialization voltage lines VIL, gate lines GL, auxiliary gate lines BGL, data lines DL, second voltage lines VSL, and vertical voltage lines VVSL.

The pixels SP may include first to third pixels SP1, SP2 and SP3. The pixel circuit of the first pixel SP1, the pixel circuit of the third pixel SP3 and the pixel circuit of the second pixel SP2 may be arranged in the direction opposite to the second direction (y-axis direction). It should be understood, however, that the disclosure is not limited thereto.

The first voltage line VDL may be disposed on a first metal layer MTL1 on the substrate SUB. The first voltage lines VDL may be disposed on the left side of the pixel circuits of the first to third pixels SP1, SP2 and SP3. The first voltage line VDL may overlap a first auxiliary electrode AUE1 of a second metal layer MTL2 and a second auxiliary electrode AUE2 of a third metal layer MTL3. The second metal layer MTL2 may be disposed on the gate insulator GI covering an active layer ACTL, and the third metal layer MTL3 may be disposed on an interlayer dielectric layer ILD covering the second metal layer MTL2. A protective layer PV may cover the third metal layer MTL3. The first auxiliary electrode AUE1 may be connected to the first voltage line VDL through multiple thirty-sixth contact holes CNT36. The second auxiliary electrode AUE2 connected to the pixel circuits of the first and third pixels SP1 and SP3 may be formed integrally with the horizontal voltage line HVDL, but the disclosure is not limited thereto. The second auxiliary electrode AUE2 connected to the pixel circuit of the second pixel SP2 may be connected to the first voltage line VDL through a thirty-seventh contact hole CNT37. The first voltage line VDL may be connected to the first and second auxiliary electrodes AUE1 and AUE2 to reduce line resistance.

The second auxiliary electrode AUE2 may be connected to the drain electrode DE1 of the first transistor ST1 of the first pixel SP1 through a first contact hole CNT1, the drain electrode DE1 of the first transistor ST1 of the second pixel SP2 through a twelfth contact hole CNT12, and the drain electrode DE1 of the first transistor ST1 of the third pixel SP3 through a twenty-third hole CNT23. Accordingly, the first voltage line VDL may supply a driving voltage to the first to third pixels SP1, SP2 and SP3 through the second auxiliary electrode AUE2.

The horizontal voltage line HVDL may be disposed on the third metal layer MTL3. The horizontal voltage line HVDL may be disposed on the upper side of the pixel circuit of the first pixel SP1. The horizontal voltage line HVDL may be connected to the first voltage line VDL through multiple thirty-fifth contact holes CNT35 to receive a driving voltage. The horizontal voltage line HVDL may provide a driving voltage or a high-level voltage to a first electrode RME1 of a fourth metal layer MTL4 through multiple forty-fourth contact holes CNT44.

The initialization voltage line VIL may be disposed on the first metal layer MTL. The initialization voltage line VIL may be disposed on the left side of the first voltage line VDL. The initialization voltage line VIL may overlap a fifth auxiliary electrode AUE5 of the third metal layer MTL3. The fifth auxiliary electrode AUE5 may be connected to the initialization voltage line VIL through multiple fortieth contact holes CNT40. The initialization voltage line VIL may be connected to the fifth auxiliary electrode AUE5 to reduce line resistance.

An eleventh connection electrode CE11 may be formed integrally with the fifth auxiliary electrode AUE5 and may be extended from the fifth auxiliary electrode AUE5. The eleventh connection electrode CE11 may be extended in the first direction (x-axis direction) between the pixel circuits of the second and third pixels SP2 and SP3, may overlap the auxiliary gate lines BGL and may be extended in the second direction (y-axis direction) and the opposite direction to the second direction (y-axis direction). The eleventh connection electrode CE11 may be connected to a source electrode SE3 of the third transistor ST3 of the first pixel SP1 through a ninth contact hole CNT9; may be connected to the source electrode SE3 of the third transistor ST3 of the second pixel SP2 through a twentieth contact hole CNT20, and may be connected to the source electrode SE3 of the third transistor ST3 of the third pixel SP3 through a thirty-first contact hole CNT31. Accordingly, the initialization voltage line VIL may supply an initialization voltage to the third transistor ST3 of each of the first to third pixels SP1, SP2 and SP3 through the eleventh connection electrode CE11, and may receive a sensing signal from the third transistor ST3.

The vertical voltage line VVSL may be disposed on the first metal layer MTL1. The vertical voltage line VVSL may be disposed on the left side of the initialization voltage line VIL. The vertical voltage line VVSL may overlap a third auxiliary electrode AUE3 of the second metal layer MTL2 and a fourth auxiliary electrode AUE4 of the third metal layer MTL3. The third auxiliary electrode AUE3 may be connected to the vertical voltage line VVSL through multiple thirty-eighth contact holes CNT38. The fourth auxiliary electrode AUE4 may be connected to the vertical voltage line VVSL through multiple thirty-ninth contact holes CNT39. The vertical voltage line VVSL may be connected to the third and fourth auxiliary electrodes AUE3 and AUE4 to reduce line resistance. The vertical voltage line VVSL may be connected to the second voltage line VSL through a forty-third contact hole CNT43. The vertical voltage line VVSL may supply a low-level voltage to the second voltage line VSL.

The second voltage line VSL may be disposed on the third metal layer MTL3. The second voltage line VSL may be disposed on the lower side of the gate line GL. The second voltage line VSL may provide a low-level voltage to the second electrode RME2 of the fourth metal layer MTL4 through multiple forty-fifth contact holes CNT45. The second voltage line VSL may provide a low-level voltage to the fifth contact electrode CTE5 of the fifth metal layer MTL5 through the forty-sixth contact hole CNT46.

The gate line GL may be disposed on the third metal layer MTL3. The gate lines GL may be disposed on the lower side of the pixel circuit of the second pixel SP2. The gate line GL may be connected to the auxiliary gate line BGL through a forty-first contact hole CNT41. The gate lines GL may provide the gate signals received from the gate driver 260 to the auxiliary gate lines BGL.

The auxiliary gate lines BGL may be disposed in the second metal layer MTL2. The auxiliary gate lines BGL may be extended in the second direction (y-axis direction) from the horizontal gate lines HGL. The auxiliary gate lines BGL may be disposed on the right side of the pixel circuits of the first to third pixels SP1, SP2 and SP3. The auxiliary gate lines BGL may supply the gate signals received from the gate lines GL to the second and third transistors ST2 and ST3 of each of the first to third pixels SP1, SP2 and SP3.

The first data line DL1 may be disposed on the first metal layer MTL1. The first data line DL1 may be disposed on the right side of the auxiliary gate line BGL. The second connection electrode CE2 of the third metal layer MTL3 may be connected to the first data line DL1 through the fourth contact hole CNT4 and may be connected to the drain electrode DE2 of the second transistor ST2 of the first pixel SP1 through the fifth contact hole CNT5. Accordingly, the first data line DL1 may supply a data voltage to the second transistor ST2 of the first pixel SP1 through the second connection electrode CE2.

The second data line DL2 may be disposed on the first metal layer MTL1. The second data line DL2 may be disposed on the right side of the first data line DL1. The fifth connection electrode CE5 of the third metal layer MTL3 may be connected to the second data line DL2 through the fifteenth contact hole CNT15 and may be connected to the drain electrode DE2 of the second transistor ST2 of the second pixel SP2 through the sixteenth contact hole CNT16. Accordingly, the second data line DL2 may supply a data voltage to the second transistor ST2 of the second pixel SP2 through the fifth connection electrode CE5.

The third data line DL3 may be disposed on the first metal layer MTL1. The third data line DL3 may be disposed on the right side of the second data line DL2. An eighth connection electrode CE8 of the third metal layer MTL3 may be connected to the third data line DL3 through the twenty-sixth contact hole CNT26 and may be connected to the drain electrode DE2 of the second transistor ST2 of the third transistor SP3 through the twenty-seventh contact hole CNT27. Accordingly, the third data line DL3 may supply a data voltage to the second transistor ST2 of the third pixel SP3 through the eighth connection electrode CE8.

The pixel circuit of the first pixel SP1 may include the first to third transistors ST1, ST2 and ST3. The first transistor ST1 of the first pixel SP1 may include an active area ACT1, a gate electrode GE1, a drain electrode DE1, and a source electrode SE1. The active region ACT1 of the first transistor ST1 may be disposed in the active layer ACTL, and may overlap the gate electrode GE1 of the first transistor ST1. The active layer ACTL may be disposed on the buffer layer BF covering the first metal layer MTL1.

The gate electrode GE1 of the first transistor ST1 may be disposed in the second metal layer MTL2. The gate electrode GE1 of the first transistor ST1 may be a part of the first capacitor electrode CPE1 of the first capacitor C1.

The drain electrode DE1 and the source electrode SE1 of the first transistor ST1 may be formed into a conductor by heat-treating the active layer ACTL. The drain electrode DE1 and the source electrode SE1 may be made conductive as an n-type semiconductor, but the disclosure is not limited thereto. The drain electrode DE1 of the first transistor ST1 may be electrically connected to the first voltage line VDL through the second auxiliary electrode AUE2. The drain electrode DE1 of the first transistor ST1 may receive a driving voltage from the first voltage line VDL.

The source electrode SE1 of the first transistor ST1 may be connected to a first connection electrode CE1 through a second contact hole CNT2. The first connection electrode CE1 may be connected to a second capacitor electrode CPE2 of the first metal layer MTL1 through a third contact hole CNT3. Accordingly, the first capacitor C1 may be formed between the first capacitor electrode CPE1 and the second capacitor electrode CPE2 as well as between the first capacitor electrode CPE1 and the first connection electrode CE1.

The first anode connection electrode ANE1 may be disposed on the third metal layer MTL3. The first anode connection electrode ANE1 may be connected to an extended part of the second capacitor electrode CPE2 through a tenth contact hole CNT10, and may be electrically connected to the light-emitting elements ED of the first pixel SP1 through an eleventh contact hole CNT11. Accordingly, the first anode connection electrode ANE1 may supply the driving current received from the pixel circuit of the first pixel SP1 to the light-emitting elements ED.

The second transistor ST2 of the first pixel SP1 may include an active area ACT2, a gate electrode GE2, a drain electrode DE2 and a source electrode SE2. The active area ACT2 of the second transistor ST2 may be disposed in the active layer ACTL, and may overlap the gate electrode GE2 of the second transistor ST2.

The gate electrode GE2 of the second transistor ST2 may be disposed in the second metal layer MTL2. The gate electrode GE2 of the second transistor ST2 may be a part of the auxiliary gate line BGL.

The drain electrode DE2 and the source electrode SE2 of the second transistor ST2 may be formed into a conductor by heat-treating the active layer ACTL. The drain electrode DE2 of the second transistor ST2 may be electrically connected to the first data line DL1 through the second connection electrode CE2. The second connection electrode CE2 of the third metal layer MTL3 may be connected to the first data line DL1 through the fourth contact hole CNT4 and may be connected to the drain electrode DE2 of the second transistor ST2 of the first pixel SP1 through the fifth contact hole CNT5. Accordingly, the first data line DL1 may supply a data voltage to the second transistor ST2 of the first pixel SP1 through the second connection electrode CE2.

The source electrode SE2 of the second transistor ST2 may be electrically connected to the first capacitor electrode CPE1 of the first capacitor C1 through a third connection electrode CE3. The third connection electrode CE3 of the third metal layer MTL3 may be connected to the source electrode SE2 of the second transistor ST2 through a sixth contact hole CNT6, and may be connected to the first capacitor electrode CPE1 of the first capacitor C1 through a seventh contact hole CNT7.

The third transistor ST3 of the first pixel SP1 may include an active area ACT3, a gate electrode GE3, a drain electrode DE3 and a source electrode SE3. The active area ACT3 of the third transistor ST3 may be disposed in the active layer ACTL, and may overlap the gate electrode GE3 of the third transistor ST3.

The gate electrode GE3 of the third transistor ST3 may be disposed at the second metal layer MTL2. The gate electrode GE3 of the third transistor ST3 may be a part of the auxiliary gate line BGL.

The drain electrode DE3 and the source electrode SE3 of the third transistor ST3 may be formed into a conductor by heat-treating the active layer ACTL. The drain electrode D3 of the third transistor ST3 may be connected to the first connection electrode CE1 through the eighth contact hole CNT8. The drain electrode DE3 of the third transistor ST3 may be electrically connected to the source electrode SE1 of the first transistor ST1 and the second capacitor electrode CPE2 of the first capacitor C1 through the first connection electrode CE1.

The source electrode SE3 of the third transistor ST3 may be electrically connected to the initialization voltage line VIL through the eleventh connection electrode CE11. The eleventh connection electrode CE11 may be connected to the source electrode SE3 of the third transistor ST2 through the ninth contact hole CNT9 and may be electrically connected to the initialization voltage line VIL through the fifth auxiliary electrode AUE5. The source electrode SE3 of the third transistor ST3 may receive an initialization voltage from the initialization voltage line VIL. The source electrode SE3 of the third transistor ST3 may supply a sensing signal to the initialization voltage line VIL.

The pixel circuit of the second pixel SP2 may include the first to third transistors ST1, ST2 and ST3. The first transistor ST1 of the second pixel SP2 may include an active area ACT1, a gate electrode GE1, a drain electrode DE1, and a source electrode SE1. The active region ACT1 of the first transistor ST1 may be disposed in the active layer ACTL, and may overlap with the gate electrode GE1 of the first transistor ST1.

The gate electrode GE1 of the first transistor ST1 may be disposed in the second metal layer MTL2. The gate electrode GE1 of the first transistor ST1 may be a part of the first capacitor electrode CPE1 of the first capacitor C1.

The drain electrode DE1 and the source electrode SE1 of the first transistor ST1 may be formed into a conductor by heat-treating the active layer ACTL. The drain electrode DE1 and the source electrode SE1 may be made conductive as an n-type semiconductor, but the disclosure is not limited thereto. The drain electrode DE1 of the first transistor ST1 may be electrically connected to the first voltage line VDL through the second auxiliary electrode AUE2. The drain electrode DE1 of the first transistor ST1 may receive a driving voltage from the first voltage line VDL.

The source electrode SE1 of the first transistor ST1 may be connected to a fourth connection electrode CE4 through a thirteenth contact hole CNT13. The fourth connection electrode CE4 may be connected to a second capacitor electrode CPE2 of the first metal layer MTL1 through a fourteenth contact hole CNT14. Accordingly, the first capacitor C1 may be formed between the first capacitor electrode CPE1 and the second capacitor electrode CPE2 as well as between the first capacitor electrode CPE1 and the fourth connection electrode CE4.

The second anode connection electrode ANE2 may be disposed on the third metal layer MTL3. The second anode connection electrode ANE2 may be connected to an extended part of the second capacitor electrode CPE2 through a twenty-first contact hole CNT21, and may be electrically connected to the light-emitting elements ED of the second pixel SP2 through a twenty-second contact hole CNT22. Accordingly, the second anode connection electrode ANE2 may supply the driving current received from the pixel circuit of the second pixel SP2 to the light-emitting elements ED.

The second transistor ST2 of the second pixel SP2 may include an active area ACT2, a gate electrode GE2, a drain electrode DE2 and a source electrode SE2. The active area ACT2 of the second transistor ST2 may be disposed in the active layer ACTL, and may overlap with the gate electrode GE2 of the second transistor ST2.

The gate electrode GE2 of the second transistor ST2 may be disposed in the second metal layer MTL2. The gate electrode GE2 of the second transistor ST2 may be a part of the auxiliary gate line BGL.

The drain electrode DE2 and the source electrode SE2 of the second transistor ST2 may be formed into a conductor by heat-treating the active layer ACTL. The drain electrode DE2 of the second transistor ST2 may be electrically connected to the second data line DL2 through the fifth connection electrode CE5. The fifth connection electrode CE5 of the third metal layer MTL3 may be connected to the second data line DL2 through the fifteenth contact hole CNT15 and may be connected to the drain electrode DE2 of the second transistor ST2 of the second pixel SP2 through the sixteenth contact hole CNT16. Accordingly, the second data line DL2 may supply a data voltage to the second transistor ST2 of the second pixel SP2 through the fifth connection electrode CE5.

The source electrode SE2 of the second transistor ST2 may be electrically connected to the first capacitor electrode CPE1 of the first capacitor C1 through the sixth connection electrode CE6. The sixth connection electrode CE6 of the third metal layer MTL3 may be connected to the source electrode SE2 of the second transistor ST2 through a seventeenth contact hole CNT17, and may be connected to the first capacitor electrode CPE1 of the first capacitor C1 through an eighteenth contact hole CNT18.

The third transistor ST3 of the second pixel SP2 may include the active area ACT3, the gate electrode GE3, the drain electrode DE3 and the source electrode SE3. The active area ACT3 of the third transistor ST3 may be disposed in the active layer ACTL, and may overlap with the gate electrode GE3 of the third transistor ST3.

The gate electrode GE3 of the third transistor ST3 may be disposed at the second metal layer MTL2. The gate electrode GE3 of the third transistor ST3 may be a part of the auxiliary gate line BGL.

The drain electrode DE3 and the source electrode SE3 of the third transistor ST3 may be formed into a conductor by heat-treating the active layer ACTL. The drain electrode D3 of the third transistor ST3 may be connected to the first connection electrode CE1 through a nineteenth contact hole CNT9. The drain electrode DE3 of the third transistor ST3 may be electrically connected to the source electrode SE1 of the first transistor ST1 and the second capacitor electrode CPE2 of the first capacitor C1 through the fourth connection electrode CE4.

The source electrode SE3 of the third transistor ST3 may be electrically connected to the initialization voltage line VIL through the eleventh connection electrode CE11. The eleventh connection electrode CE11 may be connected to the source electrode SE3 of the third transistor ST2 through the twentieth contact hole CNT20 and may be electrically connected to the initialization voltage line VIL through the fifth auxiliary electrode AUE5. The source electrode SE3 of the third transistor ST3 may receive an initialization voltage from the initialization voltage line VIL. The source electrode SE3 of the third transistor ST3 may supply a sensing signal to the initialization voltage line VIL.

The pixel circuit of the third pixel SP3 may include the first to third transistors ST1, ST2 and ST3. The first transistor ST1 of the third pixel SP3 may include the active area ACT1, the gate electrode GE1, the drain electrode DE1 and the source electrode SE1. The active region ACT1 of the first transistor ST1 may be disposed in the active layer ACTL, and may overlap with the gate electrode GE1 of the first transistor ST1.

The gate electrode GE1 of the first transistor ST1 may be disposed in the second metal layer MTL2. The gate electrode GE1 of the first transistor ST1 may be a part of the first capacitor electrode CPE1 of the first capacitor C1.

The drain electrode DE1 and the source electrode SE1 of the first transistor ST1 may be formed into a conductor by heat-treating the active layer ACTL. The drain electrode DE1 and the source electrode SE1 may be made conductive as an n-type semiconductor, but the disclosure is not limited thereto. The drain electrode DE1 of the first transistor ST1 may be electrically connected to the first voltage line VDL through the second auxiliary electrode AUE2. The drain electrode DE1 of the first transistor ST1 may receive a driving voltage from the first voltage line VDL.

The source electrode SE1 of the first transistor ST1 may be connected to the seventh connection electrode CE7 through the twenty-fourth contact hole CNT24. The seventh connection electrode CE7 may be connected to the second capacitor electrode CPE2 of the first metal layer MTL1 through a twenty-fifth contact hole CNT25. Accordingly, the first capacitor C1 may be formed between the first capacitor electrode CPE1 and the second capacitor electrode CPE2 as well as between the first capacitor electrode CPE1 and the seventh connection electrode CE7.

The tenth connection electrode CE10 may be disposed on the first metal layer MTL1. The tenth connection electrode CE10 may electrically connect an extended part of the seventh connection electrode CE7 with the third anode connection electrode ANE3. The tenth connection electrode CE10 may be connected to a first extended part of the seventh connection electrode CE7 through a thirty-second hole CNT32, and may be connected to the third anode connection electrode ANE3 through a thirty-third contact hole CNT33.

The third anode connection electrode ANE3 may be disposed in the third metal layer MTL3. The third anode connection electrode ANE3 may be electrically connected to the light-emitting elements ED of the third pixels SP3 through a thirty-fourth contact hole CNT34. Accordingly, the third anode connection electrode ANE3 may supply the driving current received from the pixel circuit of the third pixel SP3 to the light-emitting elements ED.

The second transistor ST2 of the third pixel SP3 may include the active area ACT2, the gate electrode GE2, the drain electrode DE2 and the source electrode SE2. The active area ACT2 of the second transistor ST2 may be disposed in the active layer ACTL, and may overlap with the gate electrode GE2 of the second transistor ST2.

The gate electrode GE2 of the second transistor ST2 may be disposed in the second metal layer MTL2. The gate electrode GE2 of the second transistor ST2 may be a part of the auxiliary gate line BGL.

The drain electrode DE2 and the source electrode SE2 of the second transistor ST2 may be formed into a conductor by heat-treating the active layer ACTL. The drain electrode DE2 of the second transistor ST2 may be electrically connected to the third data line DL3 through the eighth connection electrode CE8. An eighth connection electrode CE8 of the third metal layer MTL3 may be connected to the third data line DL3 through the twenty-sixth contact hole CNT26 and may be connected to the drain electrode DE2 of the second transistor ST2 of the third transistor SP3 through the twenty-seventh contact hole CNT27. Accordingly, the third data line DL3 may supply a data voltage to the second transistor ST2 of the third pixel SP3 through the eighth connection electrode CE8.

The source electrode SE2 of the second transistor ST2 may be electrically connected to the first capacitor electrode CPE1 of the first capacitor C1 through a ninth connection electrode CE9. The ninth connection electrode CE9 of the third metal layer MTL3 may be connected to the source electrode SE2 of the second transistor ST2 through a twenty-eighth contact hole CNT28, and may be connected to the first capacitor electrode CPE1 of the first capacitor C1 through a twenty-ninth contact hole CNT29.

The third transistor ST3 of the third pixel SP3 may include the active area ACT3, the gate electrode GE3, the drain electrode DE3 and the source electrode SE3. The active area ACT3 of the third transistor ST3 may be disposed in the active layer ACTL, and may overlap with the gate electrode GE3 of the third transistor ST3.

The gate electrode GE3 of the third transistor ST3 may be disposed at the second metal layer MTL2. The gate electrode GE3 of the third transistor ST3 may be a part of the auxiliary gate line BGL.

The drain electrode DE3 and the source electrode SE3 of the third transistor ST3 may be formed into a conductor by heat-treating the active layer ACTL. The drain electrode D3 of the third transistor ST3 may be connected to the seventh connection electrode CE7 through a thirtieth contact hole CNT30. The drain electrode DE3 of the third transistor ST3 may be electrically connected to the source electrode SE1 of the first transistor ST1 and the second capacitor electrode CPE2 of the first capacitor C1 through the seventh connection electrode CE7.

The source electrode SE3 of the third transistor ST3 may be electrically connected to the initialization voltage line VIL through the eleventh connection electrode CE11. The eleventh connection electrode CE11 may be connected to the source electrode SE3 of the third transistor ST2 through a thirty-first contact hole CNT31 and may be electrically connected to the initialization voltage line VIL through the fifth auxiliary electrode AUE5. The source electrode SE3 of the third transistor ST3 may receive an initialization voltage from the initialization voltage line VIL. The source electrode SE3 of the third transistor ST3 may supply a sensing signal to the initialization voltage line VIL.

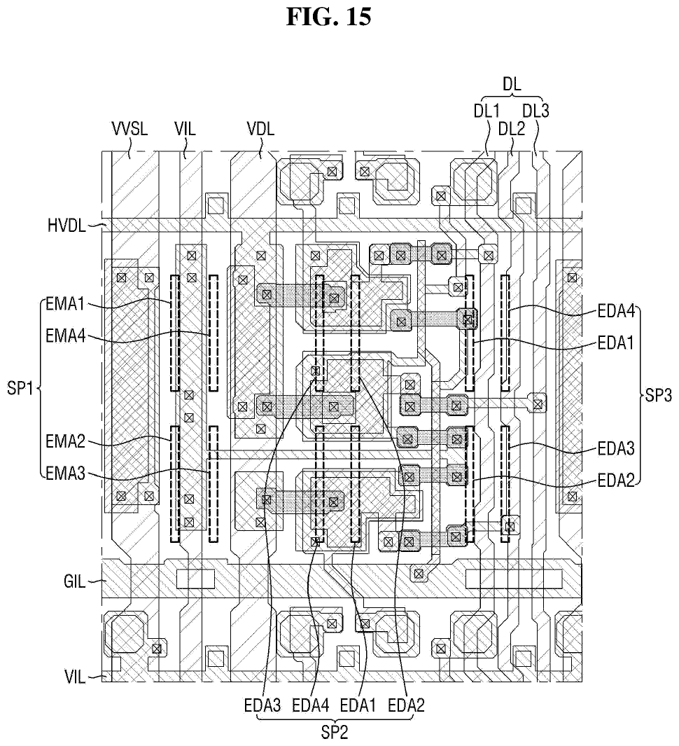

FIG. 15 is a schematic plan view showing a thin-film transistor layer and light-emitting element areas of a display device according to another embodiment.

Referring to FIG. 15, each of the first to third pixels SP1, SP2 and SP3 may include first to fourth light-emitting element areas EDA1, EDA2, EDA3 and EDA4. Multiple first light-emitting elements ED1 may be disposed in a first light-emitting element area EDA1, multiple second light-emitting elements ED2 may be disposed in a second light-emitting element area EDA2, multiple third light-emitting elements ED3 may be disposed in a third light-emitting element area EDA3, and multiple fourth light-emitting elements ED4 may be disposed in a fourth light-emitting element area EDA4.

The first to fourth light-emitting element areas EDA1, EDA2, EDA3 and EDA4 of the first pixel SP1 may overlap the initialization voltage line VIL. The initialization voltage line VIL may not receive an alignment signal during the process of aligning the light-emitting elements ED. The first voltage line VDL may receive a first alignment signal to provide it to the first electrode RME1 during the process of aligning the light-emitting elements ED, and the vertical voltage line VVSL may receive a second alignment signal to provide it to the second electrode RME2. For example, the first and second light-emitting element areas EDA1 and EDA2 may be spaced apart from the vertical voltage line VVSL and the third and fourth auxiliary electrodes AUE3 and AUE4 by about 6 μm or more. The third and fourth light-emitting element areas EDA3 and EDA4 may be spaced apart from the first voltage line VDL and the first and second auxiliary electrodes AUE1 and AUE2 by about 8 μm or more. Accordingly, the light-emitting elements ED of the first pixel SP1 suppresses the influence of the first voltage line VDL and the vertical voltage line VVSL in the alignment process, so that the reliability of the display device 10 can be improved as they are readily aligned between the first and second electrodes RME1 and RME2.

The first to fourth light-emitting element areas EDA1, EDA2, EDA3 and EDA4 of the second pixel SP2 may overlap the first capacitor C1 of each of the first to third pixels SP1, SP2 and SP3. The first capacitor C1 of each of the first to third pixels SP1, SP2 and SP3 may not receive an alignment signal during the process of aligning the light-emitting elements ED. Accordingly, the light-emitting elements ED of the second pixel SP2 suppresses the influence of the alignment signal in the alignment process, so that the reliability of the display device 10 can be improved as they are readily aligned between the first and second electrodes RME1 and RME2.

The first to fourth light-emitting element areas EDA1, EDA2, EDA3 and EDA4 of the third pixel SP3 may overlap at least one of the eleventh connection electrode CE11, and the first and second data lines DL1 and DL2. The eleventh connection electrode CE11 and the first and second data lines DL1 and DL2 may not receive an alignment signal during the process of aligning the light-emitting elements ED. Accordingly, the light-emitting elements ED of the third pixel SP3 suppresses the influence of the alignment signal in the alignment process, so that the reliability of the display device 10 can be improved as they are readily aligned between the first and second electrodes RME1 and RME2.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device, comprising:
a first voltage line disposed in a first metal layer on a substrate and that provides a high-level voltage;
a vertical voltage line disposed on a side of the first voltage line and that provides a low-level voltage;
a first transistor disposed in an active layer on the first metal layer and including:
a drain electrode electrically connected to the first voltage line;
an active region adjacent to the drain electrode;
a source electrode adjacent to the active region; and
a gate electrode disposed in a second metal layer on the active layer;
a first anode connection electrode disposed in a third metal layer on the second metal layer and electrically connected to the source electrode of the first transistor;
a first electrode and a second electrode that are disposed in a fourth metal layer on the third metal layer and extended in a first direction; and
a plurality of light-emitting element areas including a plurality of light-emitting elements aligned between the first and second electrodes and spaced apart from the first voltage line and the vertical voltage line in a plan view.

2. The display device of claim 1, further comprising:
an initialization voltage line disposed between the first voltage line and the vertical voltage line in the first metal layer,
wherein the plurality of light-emitting elements overlaps the initialization voltage line.

3. The display device of claim 2, wherein the initialization voltage line does not receive the high-level voltage or the low-level voltage in a process of aligning the plurality of light-emitting elements.

4. The display device of claim 2, further comprising:
a data line disposed in the first metal layer and that provides a data voltage;
a second transistor that provides the data voltage to the gate electrode of the first transistor;
a third transistor electrically connecting the initialization voltage line with the source electrode of the first transistor; and
a first capacitor including:
a first capacitor electrode electrically connected to the gate electrode of the first transistor; and
a second capacitor electrode electrically connected to the source electrode of the first transistor.

5. The display device of claim 4, further comprising:
a gate line disposed in the third metal layer and that provides a gate signal;
a first auxiliary gate line disposed between the first capacitor and the first data line and that provides the gate signal to the second transistor; and
a second auxiliary gate line disposed between the initialization voltage line and the first voltage line and that provides the gate signal to the third transistor.

6. The display device of claim 1, further comprising:
a first auxiliary electrode disposed in the second metal layer, overlapping the first voltage line, and electrically connected to the first voltage line; and
a second auxiliary electrode disposed in the third metal layer, overlapping the first voltage line, and electrically connected to the first voltage line.

7. The display device of claim 6, wherein the light-emitting element areas are spaced apart from the first and second auxiliary electrodes in a plan view.

8. The display device of claim 6, wherein the second auxiliary electrode electrically connects the first voltage line with the drain electrode of the first transistor.

9. The display device of claim 1, further comprising:
a third auxiliary electrode disposed in the second metal layer, overlapping the vertical voltage line, and electrically connected to the vertical voltage line; and
a fourth auxiliary electrode disposed in the third metal layer, overlapping the vertical voltage line, and electrically connected to the vertical voltage line.

10. The display device of claim 9, wherein the light-emitting element areas are spaced apart from the first and second auxiliary electrodes in a plan view.

11. The display device of claim 1, further comprising:
a horizontal voltage line disposed in the third metal layer and electrically connected to the first voltage line; and
a second voltage line disposed in the third metal layer and electrically connected to the vertical voltage line.

12. The display device of claim 11, wherein
the first electrode is electrically connected to the horizontal voltage line and receives the high-level voltage, and
the second electrode is electrically connected to the second voltage line and receives the low-level voltage.

13. The display device of claim 1, further comprising:
a first contact electrode disposed in a fifth metal layer on the fourth metal layer and electrically connected to an end of each of the light-emitting elements; and
a second contact electrode disposed in the fifth metal layer and electrically connected between an opposite end of each of the light-emitting elements and a second voltage line.

14. A display device, comprising:
a first voltage line disposed in a first metal layer on a substrate and that provides a high-level voltage;
an initialization voltage line disposed on a side of the first voltage line and that provides an initialization voltage;
a vertical voltage line disposed on the side of the first voltage line and that provides a low-level voltage;
a data line disposed in the first metal layer;
a first transistor disposed in an active layer on the first metal layer and including:
a drain electrode electrically connected to the first voltage line;
an active region adjacent to the drain electrode;
a source electrode adjacent to the active region; and
a gate electrode disposed in a second metal layer on the active layer;
a connection electrode disposed in a third metal layer on the second metal layer, electrically connected to the initialization voltage line and extended to a side of the data line;
a first electrode and a second electrode that are disposed in a fourth metal layer on the third metal layer and extended in a first direction; and
a plurality of light-emitting element areas including a plurality of light-emitting elements aligned between the first and second electrodes and spaced apart from the first voltage line and the vertical voltage line in a plan view.

15. The display device of claim 14, wherein the plurality of light-emitting elements overlaps the initialization voltage line.

16. The display device of claim 14, further comprising:
a second transistor that provides a data voltage to the gate electrode of the first transistor;
a third transistor electrically connecting the initialization voltage line with the source electrode of the first transistor; and
a first capacitor including a first capacitor electrode electrically connected to the gate electrode of the first transistor and a second capacitor electrode electrically connected to the source electrode of the first transistor.

17. The display device of claim 16, wherein the connection electrode electrically connects a source electrode of the third transistor with the initialization voltage line.

18. The display device of claim 16, further comprising:
a gate line disposed on the third metal layer and that provides a gate signal; and
an auxiliary gate line disposed between the first capacitor and the first data line and that provides the gate signal to the second and third transistors.

19. The display device of claim 18, wherein the connection electrode overlaps at least a part of the auxiliary gate line.

20. The display device of claim 14, further comprising:
an auxiliary electrode disposed in the third metal layer, overlapping the initialization voltage line, and electrically connected to the initialization voltage line,
wherein the connection electrode and the auxiliary electrode are integral to each other.
